(19) United States
(12) Patent Application Publication
(10) Pub. No.: US 2022/0090263 A1
(43) Pub. Date: Mar. 24, 2022

(54) Substrate Processing System

(71) Applicant: Kokusai Electric Corporation, Tokyo (JP)

(72) Inventors: Takashi YAHATA, Toyama (JP); Shun MATSUI, Toyama (JP); Naofumi OHASHI, Toyama (JP); Tadashi TAKASAKI, Toyama (JP)

(21) Appl. No.: 17/205,831

(22) Filed: Mar. 18, 2021

(30) Foreign Application Priority Data
Sep. 24, 2020 (JP) 2020-159826

(51) Int. Cl. C23C 16/52; C23C 16/44; C23C 16/458; C23C 16/46

(52) U.S. Cl. CPC C23C 16/52; C23C 16/46; C23C 16/4583; C23C 16/4412

(57) ABSTRACT

Described herein is a technique capable of exhausting the inner atmosphere of the gas supply pipe of the process vessel while preventing the exhaust gas from accumulating therein. According to one aspect thereof, there is provided a substrate processing system including: process vessels; a gas supply pipe connected to each process vessel; a first exhauster configured to exhaust inner atmospheres of the process vessels; a second exhauster provided separately from the first exhauster and connected to the gas supply pipe through a first switching valve; and a controller enabling to: (a) process the substrate by supplying the process gas through the gas supply pipe to a process vessel among the plurality of the process vessels; and (b) exhaust the process gas from the gas supply pipe to the second exhauster without suppling the process gas from the gas supply pipe to the process vessel.

### CROSS REFERENCE TO RELATED APPLICATIONS

This application claims foreign priority under 35 U.S.C. § 119(a)-(d) to Application No. JP 2020-159826 filed on Sep. 24, 2020, the entire contents of which are hereby incorporated by reference.

### TECHNICAL FIELD

The present disclosure relates to a substrate processing system, a method of manufacturing a semiconductor device and a non-transitory computer-readable recording medium.

### BACKGROUND

As a part of a manufacturing process of a semiconductor device, a substrate processing such as a film-forming process of forming a desired oxide film on a surface of a substrate may be performed. As an apparatus of performing the substrate processing, for example, a substrate processing system configured to process the substrate by supplying a process gas for the film-forming process such as a source gas and a reactive gas into a process vessel (process chamber) in which the substrate is accommodated may be used. For example, the process gas is supplied to the process vessel through a gas supply pipe, and the process vessel is provided with an exhauster (which is an exhaust system) capable of exhausting an inner atmosphere of the process vessel in accordance with the substrate processing.

According to the substrate processing system, for example, after the process gas is supplied into the process vessel, an inner atmosphere of the gas supply pipe is exhausted in order to constantly maintain an amount of the process gas or a quality of the process gas in the subsequent substrate processing.

However, when an exhaust pipe configured to exhaust the inner atmosphere of the gas supply pipe is connected to the exhauster capable of exhausting the inner atmosphere of the process vessel, a flow of an exhaust gas may be stagnant at a confluence of a gas exhausted from the process vessel and a gas exhausted from the gas supply pipe. Thereby, a large amount of the exhaust gas may accumulate in the exhaust pipe of the process vessel.

Therefore, the process gas remaining in the process vessel after the substrate processing may not be sufficiently exhausted by the exhauster. Then, during the subsequent substrate processing, process conditions of the substrate processing may vary depending on the process gas remaining in the process vessel. For example, a concentration of the process gas may be higher than a pre-set concentration of the process gas. As a result, a product quality of the semiconductor device may deteriorate. For example, a thickness of a film formed on the substrate may be unnecessarily thick.

In addition, the process gas remaining in the process vessel may adhere to an inner wall of the process vessel to form an unnecessary film on a surface of the inner wall. When the unnecessary film becomes thick, it may affect the substrate processing. Thus, a maintenance operation may be performed to remove the unnecessary film. However, during the maintenance operation, the process vessel under the maintenance operation cannot be used in manufacturing the semiconductor device. Therefore, a manufacturing capacity of a manufacturing line may be lowered and a yield of the semiconductor device may be lowered.

In particular, when the substrate processing system includes a plurality of process vessels, performing each process (such as a substrate transfer process, a film-forming process and a substrate unloading process) in each process vessel at slightly different timings makes it possible to reduce time waste and improve a manufacturing efficiency. However, in the substrate processing system including the plurality of the process vessels, the problems described above may occur in each of the process vessel due to the accumulation of the exhaust gas in the exhauster of the process vessel. Therefore, the problems described above may greatly affect the substrate processing system including the plurality of the process vessels.

### SUMMARY

Described herein is a technique capable of exhausting an inner atmosphere of a gas supply pipe of a process vessel while preventing an exhaust gas from accumulating in an exhaust pipe of the process vessel in a substrate processing system including a plurality of process vessels.

According to one aspect of the technique of the present disclosure, there is provided a substrate processing system including: a plurality of process vessels capable of accommodating a substrate; a gas supply pipe connected to each of the process vessels and configured to supply a process gas; a first exhauster configured to exhaust inner atmospheres of the plurality of the process vessels; a second exhauster provided separately from the first exhauster, configured to exhaust an inner atmosphere of the gas supply pipe and connected to the gas supply pipe through a first switching valve; and a controller capable of controlling the first switching valve, the first exhauster and the second exhauster to perform: (a) processing the substrate by supplying the process gas through the gas supply pipe to a process vessel among the plurality of the process vessels; and (b) exhausting the process gas from the gas supply pipe to the second exhauster while the process gas is not being supplied from the gas supply pipe to the process vessel.

### BRIEF DESCRIPTION OF THE DRAWINGS

FIG. 1 schematically illustrates a horizontal cross-section of a substrate processing system according to one or more embodiments described herein, wherein the structure shown in FIG. 1 is common with prior art.

FIG. 2 schematically illustrates a vertical cross-section of the substrate processing system according to the embodiments described herein, wherein the structure shown in FIG. 2 is common with prior art.

FIG. 3 schematically illustrates a vacuum transfer robot of the substrate processing system according to the embodiments described herein, wherein the structure shown in FIG. 3 is common with prior art.

FIG. 4 schematically illustrates the substrate processing system according to the embodiments described herein.

FIG. 5 schematically illustrates a vertical cross-section of a chamber of the substrate processing system according to the embodiments described herein.

FIG. 6 schematically illustrates a configuration of a controller of the substrate processing system and related components of the substrate processing system according to the embodiments described herein.

FIG. 7 is a flow chart schematically illustrating a first substrate processing according to the embodiments described herein.

FIG. 8 is a timing diagram schematically illustrating a sequence of the first substrate processing according to the embodiments described herein.

FIG. 9 is a flow chart schematically illustrating a substrate processing preformed in the substrate processing system according to the embodiments described herein.

### DETAILED DESCRIPTION

### Embodiments

A substrate processing system according to one or more embodiments (also simply referred to as “embodiments”) according to the technique of the present disclosure includes: a plurality of process vessels in which a substrate is accommodated; a gas supply pipe; a first exhauster; a second exhauster; and a controller configured to control the gas supply pipe, the first exhauster and the second exhauster. Hereinafter, the embodiments will be described in detail with reference to the drawings.

Hereinafter, the substrate processing system according to the embodiments will be described.

### (1) Configuration of Substrate Processing System

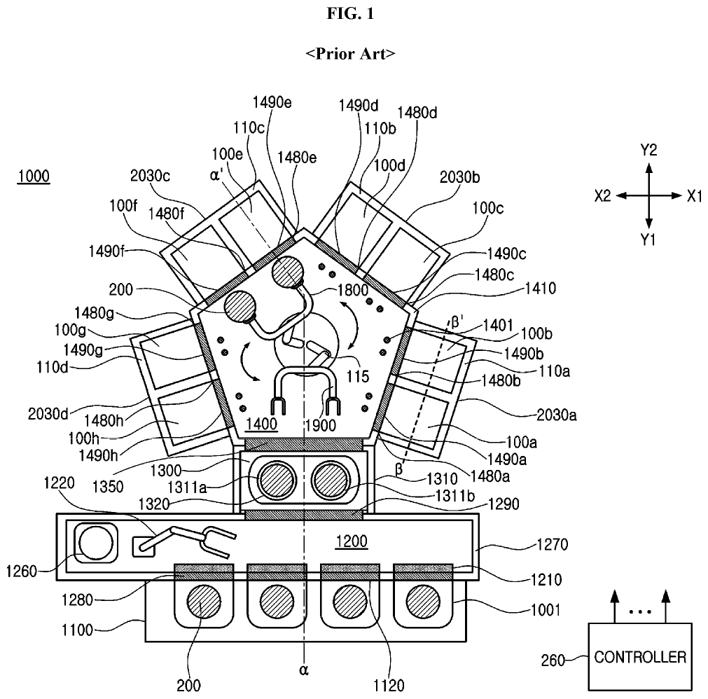

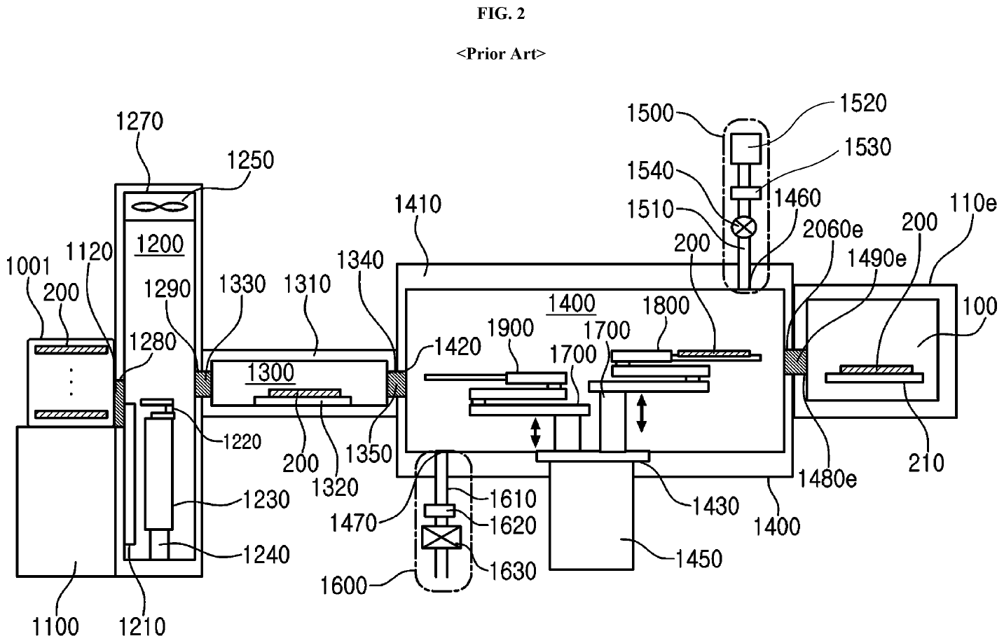

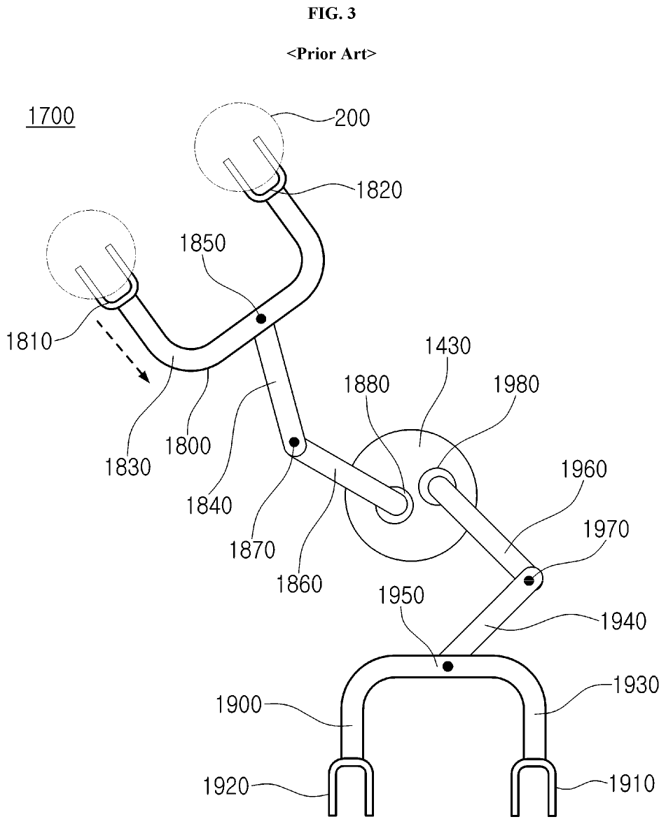

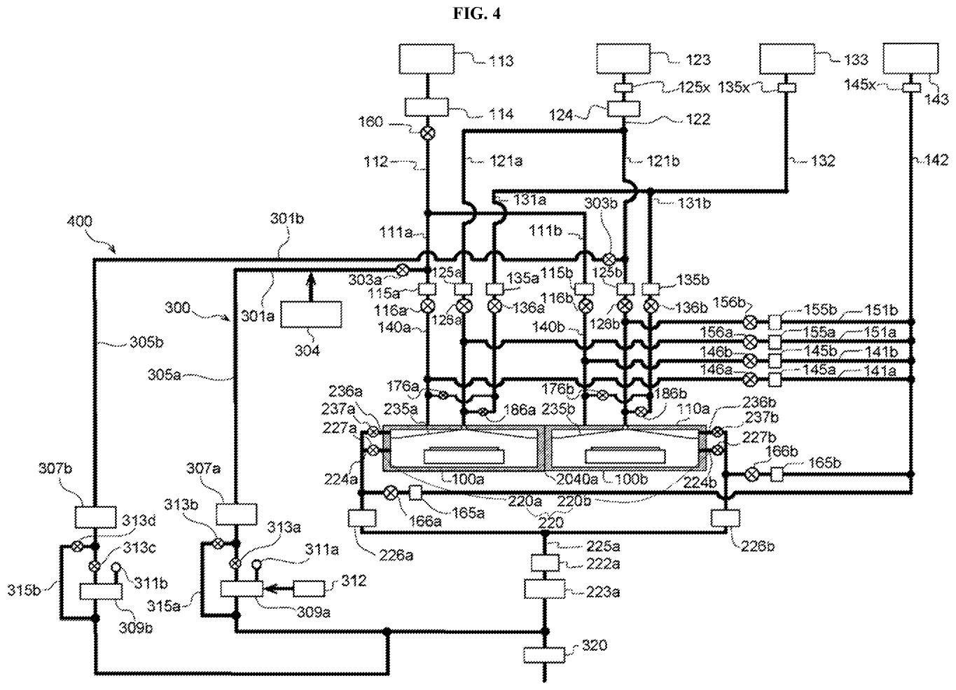

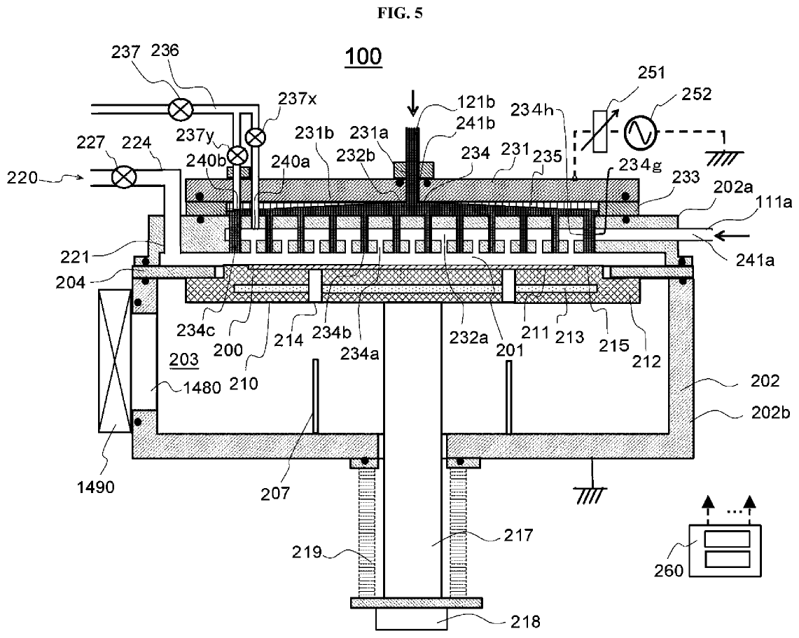

The substrate processing system according to the embodiments will be described with reference to FIGS. 1 through 5. FIG. 1 schematically illustrates a horizontal cross-section of an exemplary configuration of the substrate processing system according to the embodiments. FIG. 2 schematically illustrates a vertical cross-section of the exemplary configuration of the substrate processing system according to the embodiments taken along the line α-α′ in FIG. 1. FIG. 3 schematically illustrates arms of a vacuum transfer robot of the substrate processing system shown in FIG. 1. FIG. 4 schematically illustrates a vertical cross-section taken along the line β-β′ of FIG. 1, and schematically illustrates a gas supply system (also referred to as a “gas supplier”) configured to supply a gas into a process module of the substrate processing system and a gas exhaust system (also referred to as a “gas exhauster”) configured to exhaust the gas from the process module of the substrate processing system. FIG. 5 schematically illustrates a vertical cross-section of a chamber provided at the process module of the substrate processing system. In addition, drawings used in the following descriptions are all schematic. For example, a relationship between dimensions of each component and a ratio of each component shown in the drawings may not always match the actual ones. Further, even between the drawings, the relationship between the dimensions of each component and the ratio of each component may not always match.

Referring to FIGS. 1 and 2, a substrate processing system 1000 according to the embodiments is configured to process a plurality of wafers including a wafer 200. Hereinafter, the plurality of the wafers including the wafer 200 may also be simply referred to as wafers 200. The substrate processing system 1000 includes an I/O stage (input/output stage) 1100, an atmospheric transfer chamber 1200, a load lock chamber 1300, a vacuum transfer chamber 1400 and a plurality of process modules such as process modules 110a, 110b, 110c and 110d. Hereinafter, one of the process modules 110a, 110b, 110c and 110d may be referred to as a “process module 110”, and all of the process modules 110a, 110b, 110c and 110d may be collectively referred to as “process modules 110”.

Subsequently, a configuration of each component of the substrate processing system 1000 will be described in detail. In FIG. 1, front, rear, left and right directions are indicated by arrow Y₁, arrow Y₂, arrow X₂ and arrow X₁, respectively. In the embodiments, semiconductor devices are formed on surfaces of the wafers 200, and a substrate processing serving as a part of a manufacturing process of the semiconductor devices may be performed in the substrate processing system 1000. In the present specification, the semiconductor devices may include at least one among integrated circuits (ICs) and an electronic element (a resistance element, a coil element, a capacitor element and a semiconductor device). The semiconductor devices may further include a dummy film used in the substrate processing to manufacture the semiconductor device.

### Atmospheric Transfer Chamber and I/O Stage

The I/O stage 1100 is provided at a front portion of the substrate processing system 1000 shown FIG. 1. That is, the I/O stage 1100 is illustrated in a lower portion of FIG. 1. In the present specification, the I/O stage 1100 may also be referred to as a “loading port shelf”. The I/O stage 1100 is configured such that a plurality of pods including a pod 1001 is placed on the I/O stage 1100. Hereinafter, the plurality of the pods including the pod 1001 may also be simply referred to as pods 1001. The pod 1001 is used as a carrier for transferring a substrate (that is, the wafer 200) such as a silicon (Si) substrate. The pod 1001 is configured such that a plurality of substrates to be processed or a plurality of processed substrates may be accommodated in a multistage manner in a horizontal orientation in the pod 1001.

A cap 1120 is installed at the pod 1001. The cap 1120 is opened or closed by a pod opener 1210 described later. The pod opener 1210 is configured to open and close the cap 1120 of the pod 1001 placed on the I/O stage 1100. When the pod opener 1210 opens a substrate entrance (not shown) of the pod 1001, the wafers 200 may be loaded into or unloaded out of the pod 1001. The pod 1001 is provided to or discharged from the I/O stage 1100 by an in-process transfer device (not shown) such as a rail guided vehicle (RGV).

The I/O stage 1100 is provided adjacent to the atmospheric transfer chamber 1200. The load lock chamber 1300, which will be described later, is connected to a side of the atmospheric transfer chamber 1200 other than a side at which the I/O stage 1100 is provided.

An atmospheric transfer robot 1220, which serves as a first transfer robot configured to transfer the wafers 200, is provided in the atmospheric transfer chamber 1200. As shown in FIG. 2, the atmospheric transfer robot 1220 is elevated or lowered by an elevator 1230 installed in the atmospheric transfer chamber 1200 and is reciprocated laterally by a linear actuator 1240.

As shown in FIG. 2, a clean air supplier (which is a clean air supply system) 1250 capable of supplying clean air is installed above the atmospheric transfer chamber 1200. As shown in FIG. 1, a device (hereinafter, also referred to as a “pre-aligner”) 1260 configured to align a notch in the wafer 200 or an orientation flat is provided on a left side of the atmospheric transfer chamber 1200.

As shown in FIG. 1 and FIG. 2, a substrate loading/unloading port 1280 configured to transfer the wafers 200 into or out of the atmospheric transfer chamber 1200 and the pod opener 1210 are provided at a front side of a housing 1270 of the atmospheric transfer chamber 1200. That is, the substrate loading/unloading port 1280 and the pod opener 1210 are illustrated below the housing 1270 in FIG. 1. The I/O stage (that it, the loading port shelf) 1100 is provided at the pod opener 1210 with the substrate loading/unloading port 1280 interposed therebetween. That is, the I/O Stage 1100 is provided outside the housing 1270.

The pod opener 1210 is configured to open and close the cap 1120 of the pod 1001 placed on the I/O stage 1100. When the pod opener 1210 opens the substrate entrance (not shown) of the pod 1001, the wafers 200 may be loaded into or unloaded out of the pod 1001. The pod 1001 is provided to or discharged from the I/O stage 1100 by the in-process transfer device (not shown) such as the rail guided vehicle (RGV).

A substrate loading/unloading port 1290 configured to transfer the wafers 200 into or out of the load lock chamber 1300 is provided at a rear side of the housing 1270 of the atmospheric transfer chamber 1200. That is, the substrate loading/unloading port 1290 is illustrated above the housing 1270 in FIG. 1. The substrate loading/unloading port 1290 is opened or closed by a gate valve 1330 which will be described later. When the substrate loading/unloading port 1290 is opened by the gate valve 1330, the wafers 200 may be loaded into the load lock chamber 1300 or unloaded out of the load lock chamber 1300.

### Load Lock (L/L) Chamber

The load lock chamber 1300 is provided adjacent to the atmospheric transfer chamber 1200. The vacuum transfer chamber 1400, which will be described later, is provided at a side of a housing 1310 constituting the load lock chamber 1300 other than a side of the housing 1310 that is adjacent to the atmospheric transfer chamber 1200. Since an inner pressure of the housing 1310 is adjusted to an inner pressure of the atmospheric transfer chamber 1200 or an inner pressure of the vacuum transfer chamber 1400, the load lock chamber 1300 is constructed to withstand a negative pressure.

A substrate loading/unloading port 1340 is provided at a side of the housing 1310 adjacent to the vacuum transfer chamber 1400. The substrate loading/unloading port 1340 is opened or closed by a gate valve 1350. When the substrate loading/unloading port 1340 is opened by the gate valve 1350, the wafers 200 may be loaded into the vacuum transfer chamber 1400 or unloaded out of the vacuum transfer chamber 1400.

A substrate mounting table 1320 provided with at least two placing surfaces 1311a and 1311b is provided in the load lock chamber 1300. The wafers 200 may be placed on the at least two placing surfaces 1311a and 1311b. Hereinafter, one of the at least two placing surfaces (that is, for example, the placing surface 1311a and the placing surface 1311b) may be referred to as a “placing surface 1311”, and all of the at least two placing surfaces may be collectively referred to as “placing surfaces 1311”. A distance between the two placing surfaces 1311a and 1311b may be set based on a distance between end effectors of an arm of a vacuum transfer robot 1700 which will be described later.

### Vacuum Transfer Chamber

The substrate processing system 1000 includes the vacuum transfer chamber (also referred to as a “transfer module”) 1400, that is, a transfer space in which the wafers 200 are transferred under a negative pressure. For example, a housing 1410 constituting the vacuum transfer chamber 1400 is pentagonal when viewed from above. The load lock chamber 1300 and the process modules 110a, 110b, 110c and 110d where the wafers 200 are processed are connected to respective sides of the housing 1410 of a pentagonal shape. The vacuum transfer robot 1700 capable of transferring the wafers 200 under the negative pressure is provided at approximately at a center of the vacuum transfer chamber 1400 with a flange 1430 as a base. The vacuum transfer robot 1700 serves as a second transfer robot configured to transfer the wafers 200. While the vacuum transfer chamber 1400 of a pentagonal shape is shown in FIG. 1, the vacuum transfer chamber 1400 may be polygonal such as rectangular and hexagonal.

A substrate loading/unloading port 1420 is provided at a sidewall of the housing 1410 adjacent to the load lock chamber 1300. The substrate loading/unloading port 1420 is opened or closed by the gate valve 1350. The wafers 200 may be loaded into or unloaded out of the vacuum transfer chamber 1400 through the substrate loading/unloading port 1420.

As shown in FIG. 2, the vacuum transfer robot 1700 provided in the vacuum transfer chamber 1400 may be elevated and lowered by an elevator 1450 while maintaining the vacuum transfer chamber 1400 airtight by the flange 1430. The vacuum transfer robot 1700 will be described later in detail. The elevator 1450 is configured to elevate and lower two arms 1800 and 1900 of the vacuum transfer robot 1700 independently.

An inert gas supply hole 1460 configured to supply an inert gas into the housing 1410 is provided at a ceiling of the housing 1410. An inert gas supply pipe 1510 is provided at the inert gas supply hole 1460. An inert gas supply source 1520, a mass flow controller (also referred to as an “MFC”) 1530 and a valve 1540 are sequentially provided at the inert gas supply pipe 1510 in order from an upstream location to a downstream location of the inert gas supply pipe 1510. With such a configuration, it is possible to supply the inert gas whose supply amount is controlled into the housing 1410.

An inert gas supplier (which is an inert gas supply system) 1500 at the vacuum transfer chamber 1400 is constituted mainly by the inert gas supply pipe 1510, the MFC 1530 and the valve 1540. The inert gas supplier 1500 may further include the inert gas supply source 1520 and the inert gas supply hole 1460.

An exhaust hole 1470 configured to exhaust an inner atmosphere of the housing 1410 is provided at a bottom of the housing 1410. An exhaust pipe 1610 is provided at the exhaust hole 1470. An APC (automatic pressure controller) 1620 serving as a pressure controller and a pump 1630 are sequentially provided at the exhaust pipe 1610 in order from an upstream location to a downstream location of the exhaust pipe 1610.

A gas exhauster (which is a gas exhaust system) 1600 at the vacuum transfer chamber 1400 is constituted mainly by the exhaust pipe 1610 and the APC 1620. The gas exhaust system 1600 may further include the pump 1630 and the exhaust hole 1470.

The inner atmosphere of the vacuum transfer chamber 1400 may be controlled by the cooperation of the inert gas supplier 1500 and the gas exhauster 1600. For example, an inner pressure of the housing 1410 is controlled.

As shown in FIG. 1, the process modules 110 (that is, the process modules 110a, 110b, 110c and 110d where a desired processing is performed on the wafers 200) are connected to sidewalls of the housing 1410 other than the sidewall to which the load lock chamber 1300 is connected.

One or more chambers may be provided in each of the process modules 110a, 110b, 110c and 110d. Specifically, for example, the chambers 100a and 100b are provided in the process module 110a. The chambers 100c and 100d are provided in the process module 110b. The chambers 100e and 100f are provided in the process module 110c. The chambers 100g and 100h are provided in the process module 110d. Hereinafter, one of the chambers 100a through 100h may be referred to as a “chamber 100”, and all of the chambers 100a through 100h may be collectively referred to as “chambers 100”.

Of the sidewalls of the housing 1410, substrate loading/unloading ports 1480a, 1480b, 1480c, 1480d, 1480e, 1480f, 1480g, 1480h are provided in the sidewalls facing each of the chambers 100. For example, as shown in FIG. 2, the substrate loading/unloading port 1480e is provided in the sidewall facing the chamber 100e. Hereinafter, one of the substrate loading/unloading ports 1480a through 1480h may be referred to as a “substrate loading/unloading port 1480” or all of the substrate loading/unloading ports 1480a through 1480h may be collectively referred to as “substrate loading/unloading ports 1480”.

Similar to the substrate loading/unloading port 1480e and the chamber 100e shown in FIG. 2, the substrate loading/unloading port 1480a of FIG. 1 is provided in the sidewall facing the chamber 100a.

Similar to the substrate loading/unloading port 1480e and the chamber 100e shown in FIG. 2, the substrate loading/unloading port 1480b of FIG. 1 is provided in the sidewall facing the chamber 100b.

As shown in FIG. 1, gate valves 1490a, 1490b, 1490c, 1490d, 1490e, 1490f, 1490g, 1490h are provided at the chambers 100, respectively. Specifically, the gate valve 1490a is provided between the chamber 100a and the vacuum transfer chamber 1400; the gate valve 1490b between the chamber 100b and the vacuum transfer chamber 1400; the gate valve 1490c between the chamber 100c and the vacuum transfer chamber 1400; the gate valve 1490d between the chamber 100d and the vacuum transfer chamber 1400; the gate valve 1490e between the chamber 100e and the vacuum transfer chamber 1400; the gate valve 1490f between the chamber 100f and the vacuum transfer chamber 1400; the gate valve 1490g between the chamber 100g and the vacuum transfer chamber 1400; and the gate valve 1490h between the chamber 100h and the vacuum transfer chamber 1400. Hereinafter, one of the gate valves 1490a through 1490h may be referred to as a “gate valve 1490” or all of the gate valves 1490a through 1490h may be collectively referred to as “gate valves 1490”.

Each of the gate valves 1490 is configured to open or close the substrate loading/unloading ports 1480. The wafers 200 are transferred into or out of the chambers 100 through each of the substrate loading/unloading ports 1480.

Subsequently, the vacuum transfer robot 1700 provided in the vacuum transfer chamber 1400 will be described with reference to FIG. 3. FIG. 3 is an enlarged view of the vacuum transfer robot 1700 of FIG. 1.

The vacuum transfer robot 1700 includes the two arms 1800 and 1900. The arm 1800 includes a fork portion 1830 provided with two end effectors 1810 and 1820 at a tip (front end) thereof. A middle portion 1840 is connected to a center of the fork portion 1830 through a shaft 1850.

The wafers 200 unloaded out of each of the process modules 110 may be placed on the end effectors 1810 and 1820. In FIG. 1, for example, the wafers 200 unloaded out of the process module 110c are placed on the end effectors 1810 and 1820 of the arm 1800.

A bottom portion 1860 is connected to the middle portion 1840 via a shaft 1870 at a position different from where the fork portion 1830 is connected. The bottom portion 1860 is disposed on the flange 1430 via a shaft 1880.

The arm 1900 includes a fork portion 1930 provided with two end effectors 1910 and 1920 at a tip (front end) thereof. A middle portion 1940 is connected to a center of the fork portion 1930 through a shaft 1950.

The wafers 200 unloaded out of the load lock chamber 1300 may be placed on the end effectors 1910 and 1920.

A bottom portion 1960 is connected to the middle portion 1940 via a shaft 1970 at a position different from where the fork portion 1930 is connected. The bottom portion 1960 is disposed on the flange 1430 via a shaft 1980.

The end effector 1810 and the end effector 1820 are disposed higher than the end effector 1910 and the end effector 1920.

It is possible to rotate the vacuum transfer robot 1700 about an axis, and it is possible to extend the arms 1800 and 1900 of the vacuum transfer robot 1700.

### Process Modules

Subsequently, the process module 110a among the process modules 110 will be described with reference to FIGS. 1, 2 and 4 as an example. In FIG. 4, the process module 110a, a gas supplier (which is a gas supply system) connected to the process module 110a and a gas exhauster (which is a gas exhaust system) connected to the process module 110a are schematically illustrated.

While the process module 110a is exemplified in the present embodiments, the other process modules including the process module 110b, the process module 110c and the process module 110d are the same as the process module 110a. Accordingly, the descriptions of the process modules 110b, 110c and 110d are omitted.

As shown in FIG. 4, the process module 110a includes two chambers where the wafers 200 are processed, that is, the chamber 100a and the chamber 100b. A partition wall 2040a is provided between the chamber 100a and the chamber 100b. The partition wall 2040a is configured to prevent mixing of inner atmospheres of the chamber 100a and the chamber 100b.

As shown in FIG. 2, a substrate loading/unloading port 2060e is provided in the sidewall of the vacuum transfer chamber 1400 adjacent to the chamber 100e. Similarly, a substrate loading/unloading port (not shown) corresponding to the substrate loading/unloading port 2060e is provided in the sidewall of the vacuum transfer chamber 1400 adjacent to the chamber 100a.

A substrate support 210 configured to support the wafer 200 is provided in each of the chambers 100.

A gas supply supplier (which is a gas supply system) configured to supply gases including process gases to each of the chamber 100a and the chamber 100b is connected to the process module 110a. The gas supplier is constituted mainly by a first gas supplier (which is a source gas supplier), a second gas supplier (which is a reactive gas supplier), a third gas supplier (which is a first purge gas supplier), and a fourth gas supplier (which is a second purge gas supplier). The detailed configurations of the first gas supplier through fourth gas supplier will be described.

### First Gas Supplier

As shown in FIG. 4, a buffer tank 114, mass flow controllers (MFCs) 115a and 115b and process chamber valves 116a and 116b are provided between a source gas supply source 113 and the process module 110a. Specifically, for example, the source gas supply source 113, the buffer tank 114, the MFCs 115a and 115b and the process chamber valves 116a and 116b may be connected to a source gas common pipe 112 or source gas supply pipes 111a and 111b. The first gas supplier is constituted mainly by the source gas common pipe 112, the MFCs 115a and 115b, the process chamber valves 116a and 116b and first gas supply pipes (that is, the source gas supply pipes 111a and 111b). The first gas supplier may further include the source gas supply source 113. The same components described at the first gas supplier may be added or removed according to the number of the process modules installed in the substrate processing system 1000.

In the present embodiments, the MFCs such as the MFCs 115a and 115b described above may be a flow rate control device configured by combining an electric mass flow meter and a flow rate controller, or may be a flow rate control device such as a needle valve and an orifice. Mass flow controllers (MFCs) described later may be configured in the same manner. When the MFCs such as the MFCs 115a and 115b is implemented by the flow rate control device such as the needle valve and the orifice, it is possible to easily switch a gas supply in a pulse-wise manner at a high speed.

### Second Gas Supplier

As shown in FIG. 4, a remote plasma unit (RPU) 124 serving as an activator, mass flow controllers (MFCs) 125a and 125b and process chamber valves 126a and 126b are provided between a reactive gas supply source 123 and the process module 110a. Specifically, for example, the reactive gas supply source 123, the RPU 124, the MFCs 125a and 125b and the process chamber valves 126a and 126b may be connected to a reactive gas common pipe 122 or second gas supply pipes (that is, reactive gas supply pipes 121a and 121b). The second gas supplier is constituted mainly by the RPU 124, the MFCs 125a and 125b, the process chamber valves 126a and 126b, the reactive gas common pipe 122 and the reactive gas supply pipes 121a and 121b. The second gas supplier may further include the reactive gas supply source 123. The same components described at the second gas supplier may be added or removed according to the number of the process modules installed in the substrate processing system 1000.

According to the present embodiments, a plurality of gas supply pipes are connected to each of a plurality of process vessels to supply the process gases such as the source gas and the reactive gas. The plurality of the gas supply pipes may include the source gas supply pipes 111a and 111b configured to supply the source gas and the reactive gas supply pipes 121a and 121b configured to supply the reactive gas.

### Third Gas Supplier (First Purge Gas Supplier)

As shown in FIG. 4, for example, mass flow controllers (MFCs) 135a and 135b, process chamber valves 136a and 136b and valves 176a, 176b, 186a and 186b are provided between a first purge gas supply source (inert gas supply source) 133 and the process module 110a. Specifically, for example, the first purge gas supply source 133, the MFCs 135a and 135b, the process chamber valves 136a and 136b and the valves 176a, 176b, 186a and 186b may be connected to a purge gas common pipe (that is, an inert gas common pipe 132) or first purge gas supply pipes (that is, inert gas supply pipes 131a and 131b). The third gas supplier is constituted mainly by the MFCs 135a and 135b, the process chamber valves 136a and 136b, the inert gas common pipe 132 and the inert gas supply pipes 131a and 131b. The third gas supplier (that is, the first purge gas supplier) may further include the first purge gas supply source (inert gas supply source) 133. The same components described at the third gas supplier may be added or removed according to the number of the process modules installed in the substrate processing system 1000.

### Fourth Gas Supplier (Second Purge Gas Supplier)

As shown in FIG. 4, the fourth gas supplier is configured to supply the inert gas to the process chambers 100a and 100b through the source gas supply pipes 111a and 111b and the reactive gas supply pipes 121a and 121b. Second purge gas supply pipes 141a, 141b, 151a and 151b, mass flow controllers (MFCs) 145a, 145b, 155a and 155b and valves 146a, 146b, 156a and 156b are provided between a second purge gas supply source (inert gas supply source) 143 and the gas supply pipes 111a, 111b, 121a and 121b. The fourth gas supplier (second purge gas supplier) is constituted by these components. Although the inert gas supply sources of the third gas supplier and the fourth gas supplier are separately configured in the present embodiments, one integrated inert gas supply source may be provided for the third gas supplier and the fourth gas supplier.

A gas exhauster (which is a gas exhaust system) configured to exhaust the inner atmosphere of the chamber 100a and the inner atmosphere of the chamber 100b, respectively, is connected to the process module 110a. As shown in FIG. 4, an APC (automatic pressure controller) 222a, a common gas exhaust pipe 225a and process chamber exhaust pipes 224a and 224b (collectively denoted to as “224”) are provided between an exhaust pump 223a such as a vacuum pump and the chambers 100a and 100b. The gas exhauster is constituted mainly by the APC 222a, the common gas exhaust pipe 225a and the process chamber exhaust pipes 224a and 224b. The inner atmospheres of the chambers 100a and the chamber 100b are configured to be exhausted by a single exhaust pump, that is, the exhaust pump 223a. In addition, conductance regulators 226a and 226b configured to adjust an exhaust conductance of each of the process chamber exhaust pipes 224a and 224b, respectively, may be provided. The gas exhauster may further include the conductance regulators 226a and 226b. The gas exhauster may further include the exhaust pump 223a.

Subsequently, the chamber 100 according to the present embodiments will be described. The chamber 100 (which collectively refers to each of chambers 100a, 100b, 100c, 100d, 100e, 100f, 100g and 100h) is configured as a single wafer type substrate processing apparatus as shown in FIG. 5. A part of the manufacturing process of the semiconductor device is performed in the chamber 100. The configuration of the chambers 100a, 100b, 100c, 100d, 100e, 100f, 100g and 100h is the same as that shown in FIG. 5. Hereinafter, the chamber 100a will be described as an example.

As shown in FIG. 5, the chamber 100 includes a process vessel 202. For example, the process vessel 202 includes a flat and sealed vessel whose horizontal cross-section is circular. The process vessel 202 is made of a metal material such as aluminum (Al) and stainless steel (SUS) or quartz. A process space 201 where the wafer 200 such as a silicon wafer serving as the substrate is processed and a transfer chamber (transfer space) 203 are provided in the process vessel 202. The process vessel 202 includes an upper vessel 202a and a lower vessel 202b. A partition plate 204 is provided between the upper vessel 202a and the lower vessel 202b. In FIG. 5, a space above the partition plate 204 surrounded by the upper vessel 202a is referred to as the process space 201 and a space below the partition plate 204 surrounded by the lower vessel 202b is referred to as the transfer chamber (transfer space) 203.

The substrate loading/unloading port 1480 is provided adjacent to the gate valve 1490 at a side surface of the lower vessel 202b. The wafer 200 is transferred between the transfer chamber 203 and the vacuum transfer chamber 1400 through the substrate loading/unloading port 1480. Lift pins 207 are provided at a bottom of the lower vessel 202b. The lower vessel 202b is electrically grounded.

The substrate support 210 configured to support the wafer 200 is provided in the process space 201. The substrate support 210 includes a substrate mounting table 212 provided with a substrate placing surface 211 on which the wafer 200 is placed. Preferably, the substrate support 210 may further include a heater 213 which is a heating structure. When the substrate support 210 further includes the heater 213, the wafer 200 may be heated by the heater 213. As a result, it is possible to improve a quality of a film formed on the wafer 200. Through-holes 214 through which the lift pins 207 penetrate are provided at positions of the substrate mounting table 212 corresponding to the lift pins 207.

The substrate mounting table 212 is supported by a shaft 217. The shaft 217 penetrates a bottom of the process vessel 202 and is connected to an elevator 218 at the outside of the process vessel 202. The wafer 200 placed on the substrate placing surface 211 of the substrate mounting table 212 may be elevated and lowered by operating the elevator 218 by elevating and lowering the shaft 217 and the substrate support 210 (that is, the substrate mounting table 212). A bellows 219 covers a periphery of a lower end of the shaft 217 to maintain the process space 201 airtight.

When the wafer 200 is transferred, the substrate mounting table 212 is lowered until the substrate placing surface 211 faces the substrate loading/unloading port 1480, that is, until a wafer transfer position is reached. When the wafer 200 is processed, the substrate mounting table 212 is elevated until the wafer 200 reaches a processing position (wafer processing position) in the process space 201 as shown FIG. 5.

Specifically, when the substrate mounting table 212 is lowered to the wafer transfer position, upper ends of the lift pins 207 protrude from an upper surface of the substrate placing surface 211, and the lift pins 207 support the wafer 200 from thereunder. When the substrate mounting table 212 is elevated to the wafer processing position, the lift pins 207 are buried from the upper surface of the substrate placing surface 211 and the substrate placing surface 211 supports the wafer 200 from thereunder. Since the lift pins 207 are in direct contact with the wafer 200, the lift pins 207 are preferably made of a material such as quartz and alumina. An elevator (not shown) may also be provided at the lift pins 207. The elevator (not shown) allows the substrate mounting table 212 and lift pins 207 to move relatively.

### Exhauster

Subsequently, a first exhauster (which is a first exhaust system) 220 and a second exhauster (which is a second exhaust system) 300 according to the present embodiments will be described.

### First Exhauster

The first exhauster 220 (which collectively refers to each of first exhausters 220a and 220b) is configured to exhaust inner atmospheres of a plurality of process spaces such as the process space 201 (that is, the plurality of the process vessels). An exhaust port 221, which is a part of the first exhauster 220 configured to exhaust an inner atmosphere of the process space 201, is connected to an inner wall of the process space 201 (the upper vessel 202a). A process chamber exhaust pipe 224 and a vacuum pump such as the exhaust pump 223a are connected to the exhaust port 221 in order. The first exhauster (first exhaust line) 220 is constituted mainly by the exhaust port 221 and the process chamber exhaust pipe 224. The first exhauster 220 may further include the vacuum pump such as the exhaust pump 223a.

### Gas Introduction Port

A first gas introduction port 241a configured to supply various gases into the process space 201 is provided at a side wall of the upper vessel 202a. The first gas supply pipe (that is, the source gas supply pipe 111a) is connected to the first gas introduction port 241a. A second gas introduction port 241b configured to supply various gases into the process space 201 is provided at an upper surface (ceiling) of a shower head 234. The shower head 234 is provided at an upper portion of the process space 201. The second gas supply pipe (that is, the reactive gas supply pipe 121b) is connected to the second gas introduction port 241b. A configuration of each gas supplier connected to the first gas introduction port 241a serving as a part of the first gas supplier and the second gas introduction port 241b serving as a part of a part of the second gas supplier will be described later. Alternatively, the first gas introduction port 241a through which a first gas (that is, the source gas) is supplied may be provided on the upper surface (ceiling) of the shower head 234 so that the first gas is supplied through a center of a first buffer chamber (first buffer space) 232a. By supplying the first gas through the first buffer space 232a, the first gas in the first buffer space 232a flows from the center toward an outer periphery the first buffer space 232a. Thereby, it is possible to uniformize a flow of the first gas in the first buffer space 232a, and it is also possible to uniformize an amount of the first gas supplied to the wafer 200.

### Gas Distributor

The shower head 234 is constituted by the first buffer chamber (first buffer space) 232a, a plurality of first dispersion holes (also simply referred to as first dispersion holes) 234a, a second buffer chamber (second buffer space) 232b and a plurality of second dispersion holes (also simply referred to as second dispersion holes) 234b. The shower head 234 is provided between the second gas introduction port 241b and the process space 201. The first gas introduced through the first gas introduction port 241a is supplied to the first buffer space 232a (which is a first distributor) of the shower head 234. Further, the second gas introduction port 241b is connected to a lid 231 of the shower head 234, and the second gas introduced through the second gas introduction port 241b is supplied to the second buffer space 232b (which is a second distributor) of the shower head 234 through a hole 231a provided in the lid 231. For example, the shower head 234 is made of a material such as quartz, alumina, stainless steel and aluminum.

The lid 231 of the shower head 234 may be made of a conductive metal. The lid 231 made of the conductive metal may serve as an activator (exciter) capable of exciting the gas present in at least one among the first buffer space 232a, the second buffer space 232b and the process space 201. When the lid 231 serves as the activator, an insulating block 233 is provided between the lid 231 and the upper vessel 202a. The insulating block 233 insulates the lid 231 from the upper vessel 202a. A matcher 251 and a high frequency power supply 252 may be connected to an electrode (that is, the lid 231) serving as the activator to supply an electromagnetic wave (a high frequency power or a microwave) to the electrode (lid 231).

A gas guide 235 may be provided to form a flow of a second gas (that is, the reactive gas) supplied to the second buffer space 232b. The gas guide 235 is of a conic shape around the hole 231a. A diameter of the gas guide 235 increases along a direction from a center to an edge of the wafer 200. A diameter of a lower end of the gas guide 235 in a horizontal direction is set such that the gas guide 235 extends further outwardly than outermost peripheries of the first dispersion holes 234a and the second dispersion holes 234b.

A shower head exhaust port 240a serving as a part of a first shower head exhauster configured to exhaust an inner atmosphere of the first buffer space 232a is provided on an upper surface of an inner wall of the first buffer space 232a. A shower head exhaust pipe 236 is connected to the shower head exhaust port 240a, and a valve 237x and a valve 237 configured to control an inner pressure of the first buffer space 232a to a predetermined pressure are connected in series to the shower head exhaust pipe 236 in order. The first shower head exhauster is constituted mainly by the shower head exhaust port 240a, the valves 237 and 237x and the shower head exhaust pipe 236.

A shower head exhaust port 240b serving as a part of a second shower head exhauster configured to exhaust an inner atmosphere of the second buffer space 232b is provided on an upper surface of an inner wall of the second buffer space 232b. The shower head exhaust pipe 236 is connected to the shower head exhaust port 240b, and a valve 237y and the valve 237 configured to control an inner pressure of the second buffer space 232b to a predetermined pressure are connected in series to the shower head exhaust pipe 236 in order. The second shower head exhauster is constituted mainly by the shower head exhaust port 240b, the valves 237 and 237y and the shower head exhaust pipe 236.

### Second Exhauster

The second exhauster 300 according to the present embodiments is configured to exhaust an inner atmosphere of a gas supply pipe such as the source gas supply pipe 111a. The second exhauster 300 is provided as an exhauster separate from the first exhauster 220. Therefore, as shown in FIG. 4, the second exhauster 300 is configured to exhaust the source gas bypassing the process space 201. Specifically, the second exhauster 300 includes a source gas exhaust pipe 301a configured to exhaust the inner atmosphere of the source gas supply pipe 111a.

The source gas exhaust pipe 301a is connected to the source gas supply pipe 111a in front of the process chamber valve 116a. An end of the source gas exhaust pipe 301a opposite to the source gas supply pipe 111a is connected to a process gas exhaust pipe 305a.

### Third Exhauster

A third exhauster 400 according to the present embodiments is configured to exhaust an inner atmosphere of a gas supply pipe such as the reactive gas supply pipe 121b. The third exhauster 400 is provided as an exhauster separate from the first exhauster 220 and the second exhauster 300. Therefore, as shown in FIG. 4, the third exhauster 400 is configured to exhaust the reactive gas bypassing the process space 201. Specifically, the third exhauster 400 includes a reactive gas exhaust pipe 301b configured to exhaust the inner atmosphere of the reactive gas supply pipe 121b.

The reactive gas exhaust pipe 301b is connected to the reactive gas supply pipe 121b in front of the process chamber valve 126a (or the process chamber valve 126b). An end of the reactive gas exhaust pipe 301b opposite to the reactive gas supply pipe 121b is connected to a process gas exhaust pipe 305b. Further, the reactive gas exhaust pipe 301b is provided as an exhauster separate from the first exhauster 220 and the second exhauster 300. The reactive gas exhaust pipe 301b is included in the third exhauster 400 according to the present embodiments.

A first switching valve 303a is provided at the source gas exhaust pipe 301a. The first switching valve 303a is configured to communicate the source gas exhaust pipe 301a with the second exhauster 300. A second switching valve 303b is provided at the reactive gas exhaust pipe 301b. The second switching valve 303b is configured to communicate the reactive gas exhaust pipe 301b with the second exhauster 300 via the third exhauster 400. The first switching valve 303a and the second switching valve 303b according to the present embodiments correspond to switching valves according to the technique of the present disclosure. The switching valves according to the technique of the present disclosure refer to valves capable of allowing either the source gas exhaust pipe 301a or the reactive gas exhaust pipe 301b to communicate with the second exhauster 300. Further, the number of the switching valves is not limited to two, and may be appropriately set.

The first switching valve 303a of the source gas supply pipe 111a and the second switching valve 303b of the reactive gas exhaust pipe 301b are connected to a controller 260 described later. According to the present embodiments, both the second exhauster 300 and the third exhauster 400 are provided. However, according to the technique of the present disclosure, at least one among the second exhauster 300 and the third exhauster 400 may be provided.

The second exhauster 300 may include a heater 304. The heater 304 is connected to the source gas exhaust pipe 301a and is configured to adjust a temperature of the source gas exhaust pipe 301a to a predetermined temperature. Further, the heater 304 is connected to the controller 260. According to the technique of the present disclosure, another heater (not shown) configured to heat the reactive gas exhaust pipe 301b may be provided separately from the heater 304 or together with the heater 304 configured to heat the source gas exhaust pipe 301a.

The second exhauster 300 includes a second exhaust pump 307a connected to the process gas exhaust pipe 305a. The second exhauster (second exhaust line) 300 is constituted mainly by the source gas exhaust pipe 301a and the process gas exhaust pipe 305a. The second exhauster 300 may further include the second exhaust pump (vacuum pump) 307a.

A tank 309a capable of storing the gas exhausted by the second exhauster 300 is provided downstream of the second exhauster 300. The tank 309a is configured to be removable from an exhaust line provided with the second exhauster 300. A pressure meter 311a capable of measuring an inner pressure of the tank 309a and a temperature regulator 312 capable of adjusting a temperature of the tank 309a to a predetermined temperature are a provided at the tank 309a. The pressure meter 311a is connected to the controller 260, and a pressure value measured by the pressure meter 311a is transmitted to the controller 260. The temperature regulator 312 is connected to the controller 260, and an exhaust gas in the tank 309a can be maintained in a predetermined phase state (that is, a gaseous state, a liquid state or a solid state) by adjusting the temperature of the tank 309a by the controller 260.

A bypass line 315a is provided in parallel with the tank 309a downstream of the second exhauster 300. As shown in FIG. 4, a detoxification apparatus 320 is provided downstream of the exhaust pump 223a of the common gas exhaust pipe 225a and downstream of the first exhauster 220. That is, the detoxification apparatus 320 is illustrated in a lower portion in FIG. 4. The second exhauster 300 is connected to the detoxification apparatus 320 by connecting the tank 309a and the bypass line 315a to a location upstream of the detoxification apparatus 320 of the common gas exhaust pipe 225a. Further, line switching valves 313a and 313b are provided upstream of the tank 309a. By closing the line switching valve 313a and opening the line switching valve 313b, it is possible to supply the gas to the bypass line 315a without supplying to the tank 309a. While the present embodiments are described by way of an example in which the line switching valves 313a and 313b are configured by separate valves, the technique of the present disclosure is not limited to thereto. For example, the line switching valves 313a and 313b may be configured by a single valve such as a three-way valve.

The third exhauster 400 includes a third exhaust pump 307b connected to the process gas exhaust pipe 305b. The third exhauster (third exhaust line) 400 is constituted mainly by the reactive gas exhaust pipe 301b and the process gas exhaust pipe 305b. The third exhauster 400 may further include the third exhaust pump (vacuum pump) 307b.

A bypass line 315b is provided in parallel with a tank 309b downstream of the third exhauster 400. The third exhauster 400 is connected to the detoxification apparatus 320 by connecting the tank 309b and the bypass line 315b to a location upstream of the detoxification apparatus 320 of the common gas exhaust pipe 225a. Further, line switching valves 313c and 313d are provided a upstream of the tank 309b. By closing the line switching valve 313c and opening the line switching valve 313d, it is possible to supply the gas to the bypass line 315b without supplying to the tank 309b. While the present embodiments are described by way of an example in which the line switching valves 313c and 313d are configured by separate valves, the technique of the present disclosure is not limited to thereto. For example, the line switching valves 313c and 313d may be configured by a single valve such as a three-way valve.

While the present embodiments are described by way of an example in which the second exhauster 300 and the third exhauster 400 are connected to the process module 110a, the technique of the present disclosure is not limited to thereto. For example, the second exhauster 300 and the third exhauster 400 connected to the process module 110a may also be connected to the other process modules 110b, 110c and 110d.

Subsequently, a relationship between the first buffer space 232a included in the first gas supplier and the second buffer space 232b included in the second gas supplier will be described. The first dispersion holes 234a extend from the first buffer space 232a to the process space 201. The second dispersion holes 234b extend from the second buffer space 232b to the process space 201. The second buffer space 232b is provided above the first buffer space 232a. Therefore, as shown in FIG. 5, the second dispersion holes 234b serving as dispersion pipes from the second buffer space 232b extend into the process space 201 so as to penetrate the inside of the first buffer space 232a.

### Gas Supplier

The gas suppliers described above, for example, the first supplier through fourth gas supplier are connected to the second gas introduction port 241b connected to the lid 231 of the shower head 234 or the first gas introduction port 241a. The source gas, the reactive gas and the purge gas are supplied via the first supplier through fourth gas supplier, respectively.

### Controller

As shown in FIGS. 1 and 5, the substrate processing system 1000 includes the controller 260 configured to control operations of components of the substrate processing system 1000. For example, the controller 260 is configured to control operations of components constituting the chamber 100.

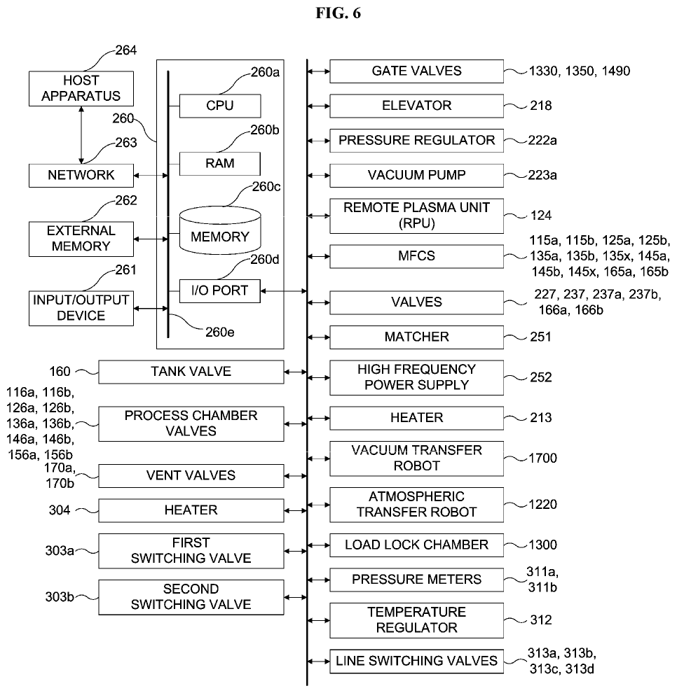

FIG. 6 is a block diagram schematically illustrating a configuration of the controller 260 and components connected to the controller 260 or controlled by the controller 260. The controller 260, which is a control apparatus (control structure) according to the present embodiments, may be embodied by a computer including a CPU (Central Processing Unit) 260a, a RAM (Random Access Memory) 260b, a memory 260c and an I/O port (input/output port) 260d. The RAM 260b, the memory 260c and the I/O port 260d may exchange data with the CPU 260a via an internal bus 260e. An input/output device 261 such as a touch panel and an external memory 262 may be additionally connected to the controller 260.

The input/output device 261 includes an output device serving as a display capable of displaying the control contents of the controller 260. The output device and a network 263 of the input/output device 261 correspond to a communication instrument according to the technique of the present disclosure. The controller 260 can communicate with a host apparatus 264 using the communication instrument.

The memory 260c may be embodied by a component such as a flash memory and a HDD (Hard Disk Drive). For example, a control program for controlling the operation of the substrate processing system 1000 and a process recipe in which information such as the sequences and the conditions of the substrate processing described later is stored are readably stored in the memory 260c. The process recipe is a program that is executed by the controller 260 to obtain a predetermined result by performing the sequences of the substrate processing. Hereinafter, the process recipe and the control program may be collectively or individually referred to simply as “program.” In the present specification, the term “program” may refer to the process recipe alone, the control program alone, or both of the process recipe and the control program. The RAM 260b serves as a memory area (work area) in which the program or the data read by the CPU 260a are temporarily stored.

The I/O port 260d is electrically connected to the components described above such as the gate valves 1330, 1350 and 1490, the elevator 218, the heater 213, a pressure regulator such as the APC 222a, a vacuum pump such as the exhaust pump 223a, the matcher 251 and the high frequency power supply 252. In addition, the I/O port 260d may be electrically connected to the atmospheric transfer robot 1220, the vacuum transfer robot 1700, and the load lock chamber 1300. The I/O port 260d may be also electrically connected to components of the process module 110a such as MFCs 115a, 115b, 125a, 125b, 125x, 135a, 135b, 135x, 145a, 145b, 145x, 155a, 155b, 165a and 165b, the valve 237 (that is, valves 237a and 237b), the process chamber valves 116a, 116b, 126a, 126b, 136a, 136b, 176a, 176b, 186a and 186b, a tank valve 160, vent valves 170a and 170b, the RPU 124, the first switching valve 303a, the second switching valve 303b, the pressure meter 311a, the temperature regulator 312, the line switching valves 313a, 313b, 313c and 313d. The I/O port 260d may be also electrically connected to similar components of the other process modules 110b, 110c and 110d described above.

The CPU 260a is configured to read and execute the control program from the memory 260c and read the process recipe in accordance with an instruction such as an operation command inputted from the input/output device 261. The CPU 260a is configured to control various operations in accordance with the process recipe such as opening and closing operations of the gate valves 1330, 1350 and 1490, an elevating and lowering operation of the elevator 218, an operation of supplying electrical power to the heater 213, a pressure adjusting operation of the pressure regulator such as the APC 222a, an ON/OFF control operation of the vacuum pump such as the exhaust pump 223a, a gas activation operation of the RPU 124, flow rate adjusting operations by the MFCs 115a, 115b, 125a, 125b, 125x, 135a, 135b, 135x, 145a, 145b, 145x, 155a, 155b, 165a and 165b, ON/OFF control operations of the gas by the valve 237, the process chamber valves 116a, 116b, 126a, 126b, 136a, 136b, 176a, 176b, 186a and 186b, the tank valve 160 and the vent valves 170a and 170b, a power matching operation of the matcher 251, and an ON/OFF control operation of the high frequency power supply 252. In addition, the CPU 260a may also be configured to control various operations in accordance with the process recipe such as operations of the components of the other process modules 110b, 110c and 110d described above.

The CPU 260a is configured to control various operations in accordance with the process recipe such as opening and closing operations of the first switching valve 303a of the second exhauster 300, the second switching valve 303b of the third exhauster 400 and the line switching valves 313a, 313b, 313c, 313d. Specifically, the CPU 260a is configured to control the gas supply pipe (that is, the source gas supply pipes 111a and 111b and the reactive gas supply pipes 121a and 121b) to perform: (a) processing the substrate by supplying a process gas such as the source gas and the reactive gas through the gas supply pipe (the source gas supply pipes 111a and 111b and the reactive gas supply pipes 121a and 121b) to the process vessel 202; and (b) exhausting the process gas from the gas supply pipe to the second exhauster 300 while the process gas is not being supplied to the process vessel 202.

In the technique of the present disclosure, it is preferable that the CPU 260a is configured to control at least one among exhausting the source gas by the second exhauster 300 and exhausting the reactive gas by the third exhauster 400 in the (b). Further, the CPU 260a is configured to control the line switching valves 313a and 313b such that the gas exhausted by the second exhauster 300 flows from the second exhauster 300 to the bypass line 315a after an inner pressure of the tank 309a reaches a predetermined pressure value or more. The CPU 260a is also configured to control the line switching valves 313c and 313d such that the gas exhausted by the third exhauster 400 flows from the third exhauster 400 to the bypass line 315b after an inner pressure of the tank 309b reaches a predetermined pressure value or more.

The CPU 260a is configured to control the communication instrument to notify the host apparatus 264 of the inner pressure of the tank 309a or the tank 309b after the inner pressure of the tank 309a or the tank 309b reaches a predetermined pressure value or more by monitoring the inner pressures of the tanks 309a and 309b. Further, the CPU 260a is configured to control temperature adjusting operations of the heater 304 and the temperature regulator 312 in accordance with the process recipe. Specifically, the CPU 260a is configured to control the heater 304 so as to heat the source gas exhaust pipe 301a to a temperature preventing the source gas from adhering to the insides of the source gas exhaust pipe 301a and the tank 309a.

The controller 260 is not limited to a dedicated computer. The controller 260 may be embodied by a general-purpose computer. For example, the controller 260 according to the present embodiments may be embodied by preparing the external memory 262 (e.g., a magnetic tape, a magnetic disk such as a flexible disk and a hard disk, an optical disk such as a CD and a DVD, a magneto-optical disk such as an MO, a semiconductor memory such as a USB memory and a memory card), and installing the program onto the general-purpose computer using the external memory 262.

The method of providing the program to the computer is not limited to the external memory 262. For example, the program may be directly provided to the computer by a communication instrument such as the network 263 (Internet and a dedicated line) instead of the external memory 262. The memory 260c and the external memory 262 may be embodied by a non-transitory computer-readable recording medium. Hereinafter, the memory 260c and the external memory 262 are collectively or individually referred to as a recording medium. In the present specification, the term “recording medium” may refer to the memory 260c alone, may refer to the external memory 262 alone, or may refer to both of the memory 260c and the external memory 262.

### (2) First Substrate Processing

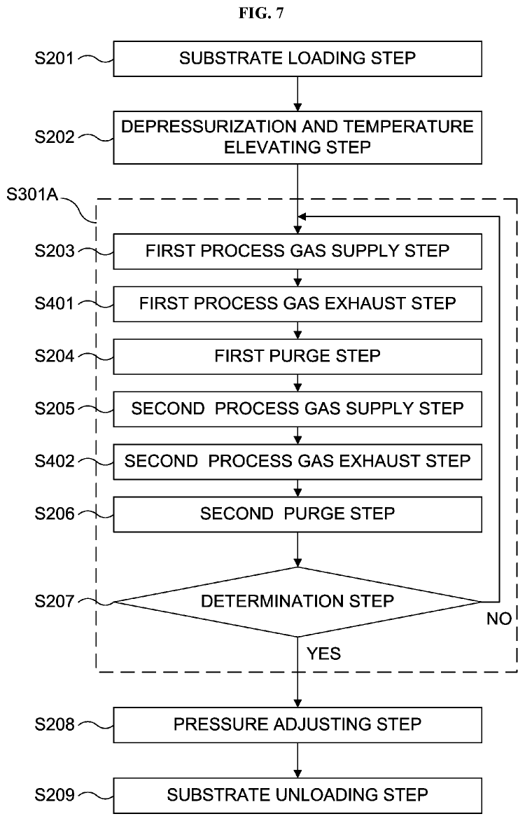

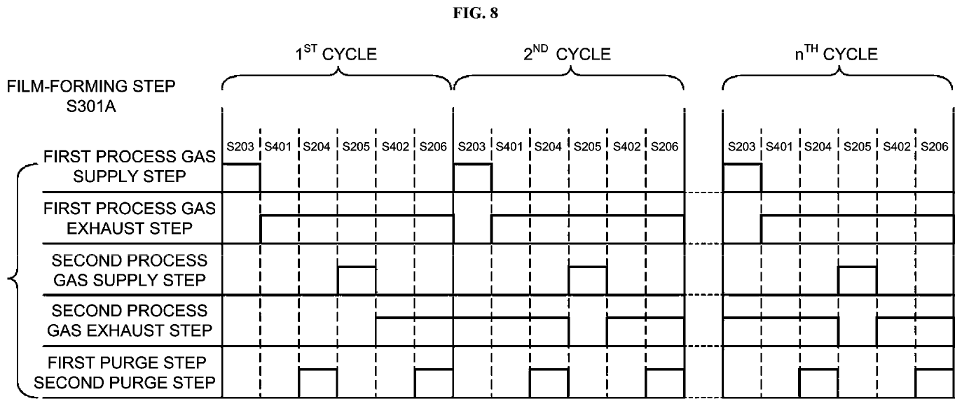

Hereinafter, as an example of the manufacturing process of the semiconductor device, an exemplary sequence of forming an insulating film (for example, a silicon oxide film (SiO film) serving as a silicon-containing film) on the wafer 200 using a furnace such as the chamber 100a of the above-described substrate processing system 1000 will be described with reference to FIGS. 7 and 8. Hereinafter, the controller 260 controls the operations of the components of the substrate processing system 1000.

In the present specification, the term “wafer” may refer to “a wafer itself” or may refer to “a wafer and a stacked structure (aggregated structure) of predetermined layers or films formed on a surface of the wafer”. That is, the term “wafer” may collectively refer to “the wafer and the layers or the films formed on the surface of the wafer. In addition, in the present specification, the term “a surface of a wafer” may refer to “a surface (exposed surface) of a wafer itself” or may refer to “a surface of a predetermined layer or a film formed on a wafer, i.e., a top surface (uppermost surface) of the wafer as a stacked structure”.

Thus, in the present specification, “supplying a predetermined gas to a wafer” may refer to “supplying a predetermined gas directly to a surface (exposed surface) of a wafer itself” or may refer to “supplying a predetermined gas to a layer or film formed on a wafer, i.e., a top surface of the wafer as a stacked structure”). In the present specification, “forming a predetermined layer (or a film) on a wafer” may refer to “forming a predetermined layer (or a film) directly on a surface (exposed surface) of a wafer itself” or may refer to “forming a predetermined layer (or a film) on a surface of a predetermined layer or a film formed on a wafer, i.e., a top surface (uppermost surface) of the wafer as a stacked structure”).

In the present specification, the terms “substrate” and “wafer” may be used as substantially the same meaning. That is, the term “wafer” may be substituted by “substrate” and vice versa.

Hereinafter, a first substrate processing S200A will be described in detail.

### Substrate Loading Step S201

First, in order to perform the first substrate processing S200A, the wafer 200 is transferred (loaded) into the process space 201. Specifically, the substrate support 210 is lowered by the elevator 218, and the lift pins 207 protrude from the upper surface of the substrate support 210 through the through-holes 214. After an inner pressure of the process space 201 is adjusted to a predetermined pressure, the gate valve 1490 is opened. Then, the wafer 200 is placed on the lift pins 207 through the gate valve 1490. After the wafer 200 is placed on the lift pins 207, the substrate support 210 is elevated to a predetermined position by the elevator 218 so that the wafer 200 is placed on the substrate support 210 from the lift pins 207.

### Depressurization and Temperature Elevating Step S202

Subsequently, the process space 201 is exhausted through the process chamber exhaust pipes 224a and 224b until the inner pressure of the process space 201 reaches and is maintained at a predetermined pressure (vacuum level). In the depressurization and temperature elevating step S202, an opening degree of the APC 222a serving as the pressure regulator is feedback-controlled based on a pressure value measured by a pressure sensor (not shown). The state of the electric conduction applied to the heater 213 is feedback-controlled based on a temperature value detected by a temperature sensor (not shown) until an inner temperature of the process space 201 reaches and is maintained at a predetermined temperature. Specifically, the substrate support 210 is heated in advance by the heater 213. The heater 213 may heat the substrate support 210 until a temperature of the wafer 200 or a temperature of the substrate support 210 is stable. When a gas desorbed from components of the process space 201 or moisture is present in the process space 201, the gas or the moisture may be removed by vacuum-exhausting the process space 201 or purging the process space 201 with N₂ gas. A preparing step before a film-forming process is now complete. It is preferable that the process space 201 is exhausted to a vacuum level that can be reached by a vacuum pump such as the exhaust pump 223a at once.

### Film-forming Step S301A>

Subsequently, an example of forming the silicon oxide film (SiO film) on the wafer 200 will be described. In particular, the film-forming step S301A including a first process gas exhaust step (source gas exhaust step) S401 and a second process gas exhaust step (reactive gas exhaust step) S402 of the first substrate processing S200A according to the present embodiments will be described in detail with reference to FIGS. 7 and 8.

After the wafer 200 is placed on the substrate support 210 and the inner atmosphere of the process space is stabilized, steps S203 through S207 shown in FIGS. 7 and 8 are performed.

### First Process Gas Supply Step S203

In the first process gas supply step S203, an aminosilane-based gas serving as the first gas (source gas) is supplied into the process space 201 by the first gas supplier. For example, according to the present embodiments, bis(diethylamino)silane (H₂Si(NEt₂)₂, abbreviated as BDEAS) gas may be used as the aminosilane-based gas. Specifically, the tank valve 160 is opened to supply the aminosilane-based gas into the chamber 100 from the source gas supply source 113. When the aminosilane-based gas is supplied, the process chamber valve 116a is opened and a flow rate of the aminosilane-based gas is adjusted by the MFC 115a. The aminosilane-based gas whose flow rate is adjusted is then supplied to the process space 201 in a depressurized state through the first buffer space 232a and gas supply holes (that is, the first dispersion holes 234a) of the shower head 234. An exhauster such as the first exhauster 220 and the second exhauster 300 continuously exhausts the process space 201 such that the inner pressure of the process space 201 is maintained at a predetermined pressure. With the inner pressure of the process space 201 is maintained at the predetermined pressure, the aminosilane-based gas is supplied to the wafer 200 in the process space 201 at a first pressure. For example, the first pressure may range from 100 Pa to 20,000 Pa. As described above, the aminosilane-based gas is supplied onto the wafer 200 in the process space 201. By supplying the aminosilane-based gas, a silicon-containing layer is formed on the wafer 200.

### First Process Gas Exhaust Step S401

After the silicon-containing layer is formed on the wafer 200, the process chamber valve 116a of the first gas supply pipe (that is, the source gas supply pipe 111a) is closed to stop the supply of the aminosilane-based gas. Then, the first switching valve 303a is opened, and as (b), the source gas is exhausted through the first gas supply pipe to the second exhauster 300 while the aminosilane-based gas (that is, the source gas) is not being supplied through the first gas supply pipe to the process vessel 202.

When the line switching valve 313a is open and the line switching valve 313b is closed, the exhausted source gas is accumulated in the tank 309a. When the line switching valve 313a is closed and the line switching valve 313b is open, the exhausted source gas flows through the bypass line 315a, and is exhausted to the outside via the detoxification apparatus 320.

As shown in FIG. 8, the first process gas exhaust step (source gas exhaust step) S401 of the present embodiments is performed while the first process gas supply step S203 is not being performed. That is, the first process gas exhaust step S401 may be performed during the first purge step S204, the second process gas supply step S205, the second process gas exhaust step S402 and the second purge step S206. According to the technique of the present disclosure, the first process gas exhaust step S401 may not be performed over the entire period while the first process gas supply step S203 is not being performed. That is, the first process gas exhaust step S401 may be performed for at least a certain time duration while the first process gas supply step S203 is not being performed. For example, the first process gas exhaust step S401 may be performed while the first purge step S204 is performed.

Further, the first process gas exhaust step S401 may be performed in one or more first gas supply pipes among a plurality of first gas supply pipes of the entire substrate processing system 1000, and simultaneously, the first process gas exhaust step S401 may not be performed in the other first gas supply pipes among the plurality of the first gas supply pipes of the entire substrate processing system 1000.

### First Purge Step S204

As described in the first process gas exhaust step S401, the process chamber valve 116a of the first gas supply pipe (that is, the source gas supply pipe 111a) is closed to stop the supply of the aminosilane-based gas. The first purge step S204 is performed by stopping the supply of the source gas (aminosilane-based gas) and exhausting the source gas present in the process space 201 or the source gas present in the first buffer space 232a through the process chamber exhaust pipe 224.

In the first purge step S204, a residual gas such as the source gas remaining in the process space 201 may be extruded by further supplying the inert gas instead of (or in parallel with) vacuum-exhausting (evacuating) the residual gas. That is, the vacuum exhaust may be combined with the supply of the inert gas. Alternatively, the vacuum exhaust and the supply of the inert gas may alternately be performed.

In the first purge step S204, the valve 237 of the shower head exhaust pipe 236 may be opened, and the residual gas present in the first buffer space 232a may be exhausted from the shower head exhaust pipe 236 via the shower head exhaust pipe 236. While exhausting the residual gas, valves 227 and 237 are controlled to adjust inner pressures (exhaust conductance) of the shower head exhaust pipe 236 and the first buffer space 232a, wherein the reference character “236” collectively refers to each of shower head exhaust pipes 236a and 236b shown in FIG. 4, “227” collectively refers to each of valves 227a and 227b shown in FIG. 4, and “237” collectively refers to each of valves 237a and 237b shown in FIG. 4. The valves 227 and 237 may be controlled such that the exhaust conductance through the shower head exhaust pipe 236 in the first buffer space 232a is higher than the exhaust conductance through the process chamber exhaust pipe 224 via the process space 201. By adjusting the exhaust conductance as described above, the residual gas flows from the first gas introduction port 241a (which is an end of the first buffer space 232a) to the shower head exhaust port 240a (which is the other end of the first buffer space 232a). Thereby, it is possible to exhaust the gas adhered to the wall (inner wall) of the first buffer space 232a and the gas floating in the first buffer space 232a from the shower head exhaust pipe 236 while preventing the gas from entering process space 201. The inner pressure of the first buffer space 232a and the inner pressure of the process space 201 (that is, the exhaust conductance) may be adjusted so as to suppress a backflow of the gas from the process space 201 into the first buffer space 232a.

In the first purge step S204, the vacuum pump such as the exhaust pump 223a continues to operate to exhaust the residual gas present in the process space 201. Further, the valves 227 and 237 may be controlled such that the exhaust conductance from the process space 201 to the process chamber exhaust pipe 224 is higher than the exhaust conductance through the first buffer space 232a. By adjusting the exhaust conductance as described above, the residual gas flows to the process chamber exhaust pipe 224 through the process space 201, and the residual gas in the process space 201 can be exhausted. In the first purge step S204, by opening the valve 136a and adjusting the MFC135a to supply the inert gas, it is possible to reliably supply the inert gas onto the wafer 200, and it is also possible to improve the efficiency of removing the residual gas on the wafer 200.

After a predetermined time has elapsed, the valve 136a is closed to stop the supply of the inert gas, and the valve 237 is closed to block a flow path from the first buffer space 232a to the shower head exhaust pipe 236.

More preferably, after the predetermined time has elapsed, the valve 237 is closed while the vacuum pump such as the exhaust pump 223a is continuously operated. Thereby, a flow of the residual gas toward the process chamber exhaust pipe 224 via the process space 201 is not affected by the shower head exhaust pipe 236 so that it is possible to more reliably supply the inert gas onto the wafer 200, and it is also possible to improve the efficiency of removing the residual gas on the wafer 200.

Purging the inner atmosphere of the process space 201 means not only evacuating and discharging the residual gas, but also pushing out the residual gas by supplying the inert gas. Therefore, in the first purge step S204, the inert gas may be supplied into the first buffer space 232a to push out the residual gas to perform a discharge operation. That is, the vacuum exhaust may be combined with the supply of the inert gas. Alternatively, the vacuum exhaust and the supply of the inert gas may alternately be performed.

In the first purge step S204, a flow rate of the N₂ gas (that is, the inert gas) supplied into the process space 201 may not be a large flow rate. For example, the first purge step S204 may be performed by supplying the N₂ gas of an amount equal to a volume of the process space 201 such that the subsequent step will not be adversely affected. By not completely purging the inside of the process space 201, it is possible to shorten a purge time for purging the process space 201, and it is also possible to improve the throughput. In addition, it is also possible to reduce the consumption of the N₂ gas to the minimum.

In the first purge step S204, a temperature of the heater 213 is set (adjusted) such that the temperature of the wafer 200 may be a predetermined temperature ranging from 200° C. to 750° C., preferably from 300° C. to 600° C., more preferably from 300° C. to 550° C., similar to the temperature of the wafer 200 in the first process gas supply step S203 of supplying the source gas onto the wafer 200. For example, each supply flow rate of the N₂ gas serving as the purge gas supplied through each inert gas supplier is set to a predetermined flow rate ranging from 100 sccm to 20,000 sccm. A rare gas such as argon (Ar) gas, helium (He) gas, neon (Ne) gas and xenon (Xe) gas may be used as the purge gas instead of the N₂ gas. In the present specification, a notation of a numerical range such as “from 200° C. to 750° C.” means that a lower limit and an upper limit are included in the numerical range. Therefore, for example, a numerical range “from 200° C. to 750° C.” means a range equal to or higher than 200° C. and equal to or lower than 750° C. The same also applies to other numerical ranges described herein.

### Second Process Gas Supply Step S205

After the first purge step S204 is completed, the process chamber valves 126a and 126b are opened, and an oxygen (O)-containing gas serving as the second gas (that is, the reactive gas) is supplied into the process space 201 via the gas introduction port (that is, the second gas introduction port 241b), the second buffer space 232b and the second dispersion holes 234b. For example, the oxygen-containing gas may include oxygen (O₂) gas, ozone (O₃) gas, water (H₂O) and nitrous oxide (N₂O) gas. In the present embodiments, for example, the oxygen gas (O₂) is used as the oxygen-containing gas. Since the oxygen-containing gas is supplied into the process space 201 through the second buffer space 232b and the second dispersion holes 234b, it is possible to uniformly supply the oxygen-containing gas onto the wafer 200. Therefore, it is possible to uniformize a thickness of a film formed on the wafer 200. The second gas may be supplied into the process space 201 in an activated state by the remote plasma unit (RPU) 124 serving as the activator (exciter).

In the second process gas supply step S205, a flow rate of the O₂ gas is adjusted by the MFCs 125a and 125b to a predetermined flow rate. For example, a supply flow rate of the 02 gas may range from 100 sccm to 10,000 sccm. A pressure controller (not shown) is appropriately adjusted in order to adjust the inner pressure of the process space 201 within a predetermined pressure range. In addition, when the O₂ gas flows through the RPU 124, the RPU 124 may be controlled to an ON state (a state that the power is turned on) to activate (excite) the O₂ gas.

When the O₂ gas is supplied to the silicon-containing layer formed on the wafer 200, the silicon-containing layer is modified. For example, the silicon-containing layer is modified to a modified layer containing silicon (Si) and oxygen (O). By providing the RPU 124 and supplying the O₂ gas activated by the RPU 124 onto the wafer 200, it is possible to form the modified layer thicker.

The modified layer of a predetermined thickness, a predetermined distribution and a predetermined penetration depth of the oxygen component is formed on the wafer 200 depending on the conditions such as the inner pressure of the process space 201, the flow rate of the O₂ gas, the temperature of the wafer 200 and the power supply condition of the RPU 124.

After a predetermined time has elapsed, the process chamber valves 126a and 126b are close to stop the supply of the O₂ gas.

### Second Process Gas Exhaust Step S40>

After the supply of the O₂ gas is stopped, the second switching valve 303b is opened, and as (b), the reactive gas is exhausted through the second gas supply pipe (that is, the reactive gas supply pipe 121b) to the third exhauster 400 while the O₂ gas (that is, the reactive gas) is not being supplied through the second gas supply pipe to the process vessel 202. When the line switching valve 313c is open and the line switching valve 313d is closed, the exhausted reactive gas is accumulated in the tank 309b. When the line switching valve 313c is closed and the line switching valve 313d is open, the exhausted reactive flows through the bypass line 315b, and is exhausted to the outside via the detoxification apparatus 320.

As shown in FIG. 8, the second process gas exhaust step (reactive gas exhaust step) S402 of the present embodiments is performed while the second process gas supply step S205 is not being performed. That is, the second process gas exhaust step S402 may be performed during the first purge step S204, the first process gas supply step S203, the first process gas exhaust step S401 and the second purge step S206. According to the technique of the present disclosure, the second process gas exhaust step S402 may not be performed over the entire period while the second process gas supply step S205 is not being performed. That is, the second process gas exhaust step S402 may be performed for at least a certain time duration while the second process gas supply step S205 is not being performed. For example, the second process gas exhaust step S402 may be performed while the second purge step S206 is performed.

Further, the second process gas exhaust step S402 may be performed in one or more second gas supply pipes among a plurality of second gas supply pipes of the entire substrate processing system 1000, and simultaneously, the second process gas exhaust step S402 may not be performed in the other second gas supply pipes among the plurality of the second gas supply pipes of the entire substrate processing system 1000.

### Second Purge Step S206

As described in the second process gas exhaust step S402, by stopping the supply of the reactive gas (O₂ gas), the O₂ gas present in the process space 201 or the O₂ gas present in the second buffer space 232b is exhausted through the first exhauster 220. By exhausting the O₂ gas, the second purge step S206 is performed. The second purge step S206 may be performed in the same manner as the first purge step S204 described above.

In the second purge step S206, the vacuum pump such as the exhaust pump 223a continues to operate to exhaust the residual gas present in the process space 201 through the process chamber exhaust pipe 224. Further, the valves 227 and 237 may be controlled such that the exhaust conductance from the process space 201 to the process chamber exhaust pipe 224 is higher than the exhaust conductance through the second buffer space 232b. By adjusting the exhaust conductance as described above, the residual gas flows to the process chamber exhaust pipe 224 through the process space 201, and the residual gas in the process space 201 can be exhausted. In the second purge step S206, by opening the process chamber valve 136b and adjusting the MFC135b to supply the inert gas, it is possible to reliably supply the inert gas onto the wafer 200, and it is also possible to improve the efficiency of removing the residual gas on the wafer 200.

After a predetermined time has elapsed, the process chamber valve 136b is closed to stop the supply of the inert gas, and the valve 237 is closed to block a flow path from the second buffer space 232b to the shower head exhaust pipe 236.

More preferably, after the predetermined time has elapsed, the valve 237 is closed while the vacuum pump such as the exhaust pump 223a is continuously operated. Thereby, a flow of the residual gas toward the shower head exhaust pipe 236 via the process space 201 is not affected by the process chamber exhaust pipe 224 so that it is possible to more reliably supply the inert gas onto the wafer 200, and it is also possible to improve the efficiency of removing the residual gas on the wafer 200.

Purging the inner atmosphere of the process space 201 means not only evacuating and discharging the residual gas, but also pushing out the residual gas by supplying the inert gas. Therefore, in the second purge step S206, the inert gas may be supplied into the second buffer space 232b to push out the residual gas to perform the discharge operation. That is, the vacuum exhaust may be combined with the supply of the inert gas. Alternatively, the vacuum exhaust and the supply of the inert gas may alternately be performed.

In the second purge step S206, the flow rate of the N₂ gas (that is, the inert gas) supplied into the process space 201 may not be a large flow rate. For example, the second purge step S206 may be performed by supplying the N₂ gas of an amount equal to the volume of the process space 201 such that the subsequent step will not be adversely affected. By not completely purging the inside of the process space 201, it is possible to shorten the purge time for purging the process space 201, and it is also possible to improve the throughput. In addition, it is also possible to reduce the consumption of the N₂ gas to the minimum.

In the second purge step S206, the temperature of the heater 213 is set (adjusted) such that the temperature of the wafer 200 may be a predetermined temperature ranging from 200° C. to 750° C., preferably from 300° C. to 600° C., more preferably from 300° C. to 550° C., similar to the temperature of the wafer 200 in the first process gas supply step S203 of supplying the source gas onto the wafer 200. For example, each supply flow rate of the N₂ gas serving as the purge gas supplied through each inert gas supplier is set to a predetermined flow rate ranging from 100 sccm to 20,000 sccm. The rare gas such as argon (Ar) gas, helium (He) gas, neon (Ne) gas and xenon (Xe) gas may be used as the purge gas instead of the N₂ gas.

### Determination Step S207

After the second purge step S206 is completed, the controller 260 determines whether a cycle (of the film-forming step S301A) including the step S203 through the step S206 is performed a predetermined number of times (n times). That is, the controller 260 determines whether a film of a desired thickness is formed on the wafer 200. An insulating film of the desired thickness and containing silicon (Si) and oxygen (O) (that is, the SiO film) may be formed by performing the cycle including the step S203 through the step S206 at least once. It is preferable that the cycle is performed a plurality of times until the SiO film of the desired thickness is formed on the wafer 200.

When the controller 260 determines, in the determination step S207, that the cycle is not performed the predetermined number of times (“NO” in FIG. 7), the cycle including the step S203 through the step S206 is repeatedly performed. When the controller 260 determines, in the determination step S207, that the cycle is performed the predetermined number of times (“YES” in FIG. 7), the film-forming step S301A is terminated and a pressure adjusting step S208 and a substrate unloading step S209 are performed.

In the first process gas supply step S203 and the second process gas supply step S205 described above, by supplying the inert gas to the second buffer space 232b which is the second distributor when the first gas is supplied and by supplying the inert gas to the first buffer space 232a which is the first distributor when the second gas is supplied, it is possible to prevent each gas from flowing back into different buffer spaces.

### Pressure Adjusting Step S208

In the pressure adjusting step S208, the process space 201 or the transfer chamber 203 is exhausted through the process chamber exhaust pipe 224 until the inner pressure of the process space 201 or an inner pressure of the transfer chamber 203 reaches and is maintained at a predetermined pressure (vacuum level). In the pressure adjusting step S208, the inner pressure of the process space 201 or the inner pressure of the transfer chamber 203 is adjusted to be equal to or greater than the inner pressure of the vacuum transfer chamber 1400. Before, during or after the pressure adjusting step S208, the wafer 200 may be supported by the lift pins 207 until the wafer 200 is cooled down to a predetermined temperature.

### Substrate Unloading Step S209

After the inner pressure of the process space 201 is adjusted to a predetermined pressure in the pressure adjusting step S208, the gate valve 1490 is opened. Then, the wafer 200 is unloaded out of the transfer chamber 203 to the vacuum transfer chamber 1400.

As described above, the wafer 200 is processed. By the way, the productivity should be improved even when an odd number of wafers are transferred to the substrate processing system 1000 provided with an even number of the chambers 100 as shown in FIGS. 1 and 4. For example, by increasing the number of wafers 200 processed per unit time (that is, a processing throughput), by maintaining a process performance, by shortening a maintenance time or by reducing a maintenance frequency, it is possible to improve the productivity. When the odd number of wafers including the wafer 200 are transferred to the process module 110a of the substrate processing system 1000 shown in FIGS. 1 and 4, for example, in the chamber 100a, the wafer 200 is processed in the chamber 100a and another wafer among the odd number of wafers is processed in the chamber 100b. According to the present embodiments, the odd number of wafers may be accommodated in the pod 1001 or in the pods 1001.

### Recipe Switching Step

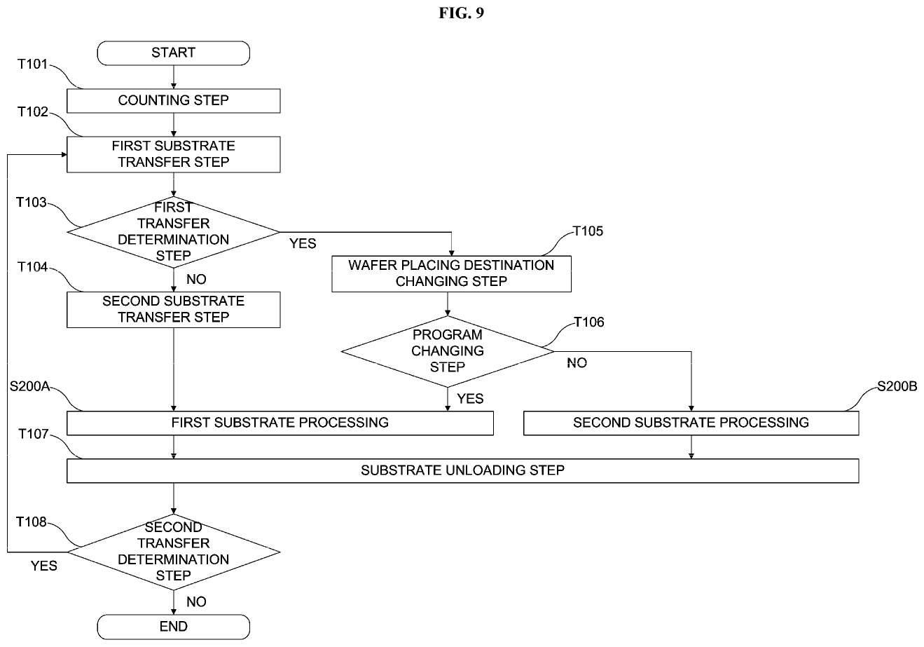

Subsequently, a recipe switching step of switching between a first program (recipe) for causing the computer to execute the first substrate processing S200A and a second program (recipe) for causing the computer to execute a second substrate processing S200B according to the presence or absence of the wafer 200 will be described with reference to FIGS. 1, 2 and 9.

### Counting Step T101

First, when the pod 1001 is placed on the I/O stage 1100, the number of wafers including the wafer 200 stored in the pod 1001 is counted, and number information of the wafers is recorded on the recording medium.

### First Substrate Transfer Step T102

The wafers including the wafer 200 stored in the pod 1001 are sequentially transferred from the pod 1001 to the load lock chamber 1300 by the atmospheric transfer robot 1220. When two wafers including the wafer 200 are stored in the load lock chamber 1300, the vacuum transfer robot 1700 transfers the two wafers from the load lock chamber 1300 to each process modules 110.

### First Transfer Determination Step T103

In the first transfer determination step T103, it is determined whether or not the wafer 200 stored in the pod 1001 is the last wafer and there is no wafer in the load lock chamber 1300. Alternatively, it is determined whether or not there is no wafer in the load lock chamber 1300 and the wafer 200 is the last wafer in the continuous processing. In the present embodiments, the continuous processing means that the substrate processing by the pod 1001 is continued between successive substrates. When the wafer 200 stored in the pod 1001 is the last wafer and there is no wafer in the load lock chamber 1300, a wafer placing destination changing step T105 is performed. When the wafer 200 stored in the pod 1001 is not the last wafer or when there is another wafer in the load lock chamber 1300, a second substrate transfer step T104 is performed.

### Second Substrate Transfer Step T104

The second substrate transfer step T104 is performed after two wafers including the wafer 200 are stored in the load lock chamber 1300. In the second substrate transfer step T104, first, an inner pressure of the load lock chamber 1300 is adjusted to the same pressure as the inner pressure of the vacuum transfer chamber 1400. After adjusting the inner pressure of the load lock chamber 1300, the gate valve 1350 is open, and the vacuum transfer robot 1700 transfers the two wafers to the process module 110 where the two wafers are processed. After the two wafers are transferred to the process module 110, the first substrate processing S200A is performed.

### Wafer Placing Destination Changing Step T105

After it is determined that the wafer 200 stored in the pod 1001 is the last wafer and there is no wafer in the load lock chamber 1300 in the first transfer determination step T103, the wafer 200 is placed on one of the placing surfaces 1311 in the load lock chamber 1300. Since the chamber 100 used in processing the wafer 200 is determined based on a placing destination of the wafer 200, the wafer 200 is placed on one of the placing surfaces 1311 in accordance with the chamber to which the wafer 200 is to be transferred. For example, when the wafer 200 is processed in one of the chambers 100a, 100c, 100e and 100g, the wafer 200 is placed on the placing surface 1311a. Alternatively, when the wafer 200 is processed in one of the chambers 100b, 100d, 100f and 100h, the wafer 200 is placed on the placing surface 1311b. When the substrate processing is performed with respect to an n^{th} lot using one of the chambers 100b, 100d, 100f and 100h, the atmospheric transfer robot 1220 is controlled to transfer and place the wafer 200 on the placing surface 1311b such that the substrate processing is performed with respect to an (n+1)^{th} lot using one of the chambers 100b, 100d, 100f and 100h. By changing the placing destination as described above, it is possible to suppress a bias in the number of times the chamber 100 is used, and it is possible to lengthen the period between a maintenance operation and its next maintenance operation of the chamber 100. That is, it is possible to reduce the maintenance frequency and it is also possible to improve the productivity. It is also possible to increase the number of wafers 200 processed per unit time (that is, the processing throughput).

### Program Changing Step T106

In the program changing step T106, based on the placing destination information, it is identified which of the chambers among the process modules 110 the wafer 200 is transferred to or not in the wafer placing destination changing step T105. Thereafter, the programs to be performed may be changed such that the first program is executed to perform the first substrate processing S200A in the chamber to which the wafer 200 is transferred, and the second program is executed to perform the second substrate processing S200B in the chamber to which the wafer 200 is not transferred.

In the program changing step T106, the programs to be performed may be changed based on the placing destination information. However, the present embodiments are not limited thereto. For example, the programs to be performed may be changed based on the presence or absence of the wafer 200 in each of the chambers 100 immediately before the wafer 200 is transferred to the chamber 100 where the wafer 200 is processed. For example, a substrate detector 1401 provided in the vacuum transfer chamber 1400 may be used to detect the presence or absence of the wafer 200. Further, the placing destination information may be compared with the presence or absence of the wafer 200 in each of the chambers 100 detected by the substrate detector 1401 provided in the vacuum transfer chamber 1400. When the placing destination information matches the presence or absence of the wafer 200 in each of the chambers 100, the wafer 200 may be transferred thereto. When the placing destination information does not match the presence or absence of the wafer 200 in each of the chambers 100, the transfer of the wafer 200 may be stopped, and information indicating an abnormal state may be notified to either or both of the input/output device 261 and the network 263.

### Substrate Unloading Step T107

A step of transferring the wafers including the wafer 200 from the process module 110 to the pod 1001 is performed. For example, the wafer 200 after the first substrate processing S200A is performed or the wafer 200 after the second substrate processing S200B is performed may be transferred to the pod 1001.

### Second Transfer Determination Step T108

In the second transfer determination step T108, it is determined whether or not an unprocessed wafer is stored in the pod 1001. When the unprocessed wafer is stored in the pod 1001, the first substrate transfer step T102 is performed. When there is no unprocessed wafer in the pod 1001, the substrate processing is terminated.

In the substrate processing system 1000 according to the present embodiments, the second exhauster 300 configured to exhaust the inner atmosphere of the gas supply pipe is provided separately from the first exhauster 220 configured to exhaust an inner atmosphere of the process vessel 202. When the process gas is exhausted by the second exhauster 300, the process gas is exhausted without being mixed with an inner atmosphere of the first exhauster 220. On the other hand, when the source gas supply pipe 111a or the reactive gas supply pipe 121b is connected to, for example, the process chamber exhaust pipe 224 of the first exhauster 220 or the shower head exhaust pipe 236 of the first shower head exhauster in FIG. 5, both the gas exhausted from the process vessel 202 and the gas exhausted from the gas supply pipe (which are collectively referred to as an “exhaust gas”) are exhausted together in the first exhauster 220. As a result, a large amount of the exhaust gas is accumulated at a confluence of the first exhauster 220.

According to the present embodiments in which the second exhauster 300 is provided separately from the first exhauster 220, it is possible to avoid an increase in a flow rate of the exhaust gas in the first exhauster 220 by preventing the exhaust gas from becoming stagnant at the confluence as compared with a case where the second exhauster 300 is connected with the first exhauster 220. Therefore, according to the present embodiments, in the substrate processing system 1000 provided with the plurality of the process vessels, it is possible to exhaust an inner atmosphere of the gas supply pipe while preventing the exhaust gas from accumulating in the exhaust pipe of each of the process vessels.

According to the present embodiments, the second exhauster 300 is controlled such that the source gas is exhausted by the second exhauster 300. Therefore, it is possible to prevent the exhaust gas from accumulating in the first exhauster 220 as compared with a case where both the source gas and the reactive gas are exhausted through the first exhauster 220.

According to the present embodiments, the third exhauster 400 is controlled such that the reactive gas is exhausted by the third exhauster 400. Therefore, it is possible to prevent the exhaust gas from accumulating in the first exhauster 220 as compared with a case where both the source gas and the reactive gas are exhausted through the first exhauster 220.

According to the present embodiments, the detoxification apparatus 320 is provided in a path of the exhaust gas. Therefore, it is possible to prevent the exhaust gas from affecting the environment.

According to the present embodiments, the tank 309a capable of storing the gas exhausted by the second exhauster 300 is provided downstream of the second exhauster 300. Therefore, by using the tank 309a, it is possible to facilitate the handling of the exhaust gas.

According to the present embodiments, the tank 309b capable of storing the gas exhausted by the third exhauster 400 is provided downstream of the third exhauster 400. Therefore, by using the tank 309b, it is possible to facilitate the handling of the exhaust gas.

According to the present embodiments, the tank 309a capable of storing the source gas and the tank 309b capable of storing the reactive gas are separately provided. Therefore, it is possible to store the source gas and the reactive gas without mixing the source gas and the reactive gas.

According to the present embodiments, pressure meters 311a and 311b and the display of the controller 260 (that is, the CPU 260a) are provided. Therefore, after the inner pressure of the tank 309a or the tank 309b reaches a predetermined pressure value or more, it is possible to notify the display of the controller 260 of the inner pressure of the tank 309a or the tank 309b. By notifying the host apparatus 264 of the inner pressure of the tank 309a or the tank 309b, it is possible to grasp a capacity of the exhaust gas in the tank 309a or the tank 309b. Therefore, for example, it is possible to remove the exhaust gas from the tank 309a or the tank 309b before the tank 309a or the tank 309b is filled with the exhaust gas.

According to the present embodiments, the controller 260 (that is, the CPU 260a) is provided with the communication instrument such as the network 263 capable of communicating with the host apparatus 264. Therefore, the host apparatus 264 other than the controller 260 may grasp the capacity of the exhaust gas in the tank 309a or the tank 309b. That is, since the capacity of the exhaust gas in the tank 309a or the tank 309b can be monitored even outside a manufacturing line, it is possible to monitor the capacity of the exhaust gas by a plurality of apparatuses such as the host apparatus 264 and the controller 260. Therefore, for example, it is possible to reduce the concern that an operation of removing the exhaust gas from the tank 309a or the tank 309b is overlooked.

According to the present embodiments, after the inner pressure of the tank 309a reaches a predetermined pressure value or more, the line switching valves 313a and 313b are controlled such that the gas exhausted by the second exhauster 300 flows to the bypass line 315a without flowing into the tank 309a. Therefore, for example, when the exhaust gas is removed from the tank 309a, by bypassing the tank 309a using the bypass line 315a, it is possible to easily perform an operation such as the operation of removing the exhaust gas.

According to the present embodiments, after the inner pressure of the tank 309b reaches a predetermined pressure value or more, the line switching valves 313c and 313d are controlled such that the gas exhausted by the third exhauster 400 flows to the bypass line 315b without flowing into the tank 309b. Therefore, for example, when the exhaust gas is removed from the tank 309b, by bypassing the tank 309b using the bypass line 315b, it is possible to easily perform the operation such as the operation of removing the exhaust gas.

According to the present embodiments, the tank 309a is configured to be removable from the exhaust line provided with the second exhauster 300. Therefore, it is possible to easily perform a maintenance operation such as a replacement operation and a cleaning operation of tank 309a.

According to the present embodiments, the tank 309b is configured to be removable from the exhaust line provided with the third exhauster 400. Therefore, it is possible to easily perform a maintenance operation such as a replacement operation and a cleaning operation of the tank 309b.

According to the present embodiments, the exhaust gas in the tank 309a can be maintained in a predetermined phase state (that is, a gaseous state, a liquid state or a solid state) by the temperature regulator 312. Therefore, it is possible to easily manage the exhaust gas.

According to the present embodiments, the state of the exhaust gas in the source gas exhaust pipe 301a can be changed by the heater 304. Therefore, it is possible to easily manage the exhausted source gas.

In particular, when the source gas adheres to the inner wall of the source gas exhaust pipe 301a, a concentration and properties of the source gas may change. In addition, particles are generated by the adhesion of the source gas. By mixing the particles in the exhaust gas, the purity of the exhaust gas may be reduced. As a result, when the exhausted source gas is reused, there may be a burden to re-adjust the quality of the source gas. By controlling the state of the exhaust gas by using the heater 304 so as to prevent the source gas from adhering to the inner wall of the source gas exhaust pipe 301a, it is possible to maintain the quality of the exhausted source gas.

According to the present embodiments, there is provided a method of manufacturing a semiconductor device capable of exhausting the inner atmosphere of the gas supply pipe of the process vessel while preventing the exhaust gas from accumulating in the exhaust pipe of the process vessel in the substrate processing system 1000 including the plurality of the process vessels.

According to the present embodiments, there is provided a program to perform the substrate processing capable of exhausting the inner atmosphere of the gas supply pipe of the process vessel while preventing the exhaust gas from accumulating in the exhaust pipe of the process vessel in the substrate processing system 1000 including the plurality of the process vessels.

According to the present embodiments, there is provided a non-transitory computer-readable recording medium storing a program, by a computer, to perform the substrate processing capable of exhausting the inner atmosphere of the gas supply pipe of the process vessel while preventing the exhaust gas from accumulating in the exhaust pipe of the process vessel in the substrate processing system 1000 including the plurality of the process vessels.

### OTHER EMBODIMENTS

While the technique is described in detail by way of the embodiments, the above-described technique is not limited thereto. For example, according to the above-described embodiments, the second exhauster 300 and the third exhauster 400 are provided separately. However, according to the above-described technique, the reactive gas exhaust pipe 301b alone may be connected to the second exhauster 300 without providing the third exhauster 400. That is, the above-described technique may also be applied to a configuration in which the second exhauster 300 is configured to exhaust both the source gas and the reactive gas.

In such a case, the source gas exhaust pipe 301a and the reactive gas exhaust pipe 301b are connected to the process gas exhaust pipe 305a. Further, the process gas exhaust pipe 305a is provided with a single second exhaust pump, which is the second exhaust pump 307a. In addition, a switching valve capable of switching the exhaust pipe is provided at a connection point of each exhaust pipe with the process gas exhaust pipe 305a. By using the switching valve described above, it is possible to switch the exhaust between the exhaust of the source gas and the exhaust of the reactive gas. That is, by using the switching valve described above, the second exhaust pump 307a can be operated for different usages as if there are two pumps. Therefore, one pump (that is, the second exhaust pump 307a) is sufficient to perform the exhaust without having to prepare two pumps.

The above-described embodiments are described by way of an example in which the first switching valve 303a is provided upstream of the MFC 115a. However, a position of the first switching valve 303a may be changed appropriately. For example, the first switching valve 303a may be provided downstream of the MFC 115a, or the first switching valve 303a may be provided downstream of both the MFCs 115a and 115b of the gas supply pipes 111a and 111b (that is, the first switching valve 303a may be provided closer to the chambers 100a and 100b). In such a case, the first switching valve 303a is provided in each of the gas supply pipes 111a and 111b. With such a configuration, it is possible to suppress the fluctuation in a flow rate of the gas supplied to each of the chambers 100a and 100b. When the first switching valve 303a is provided upstream of the MFCs 115a and 115b and the process gas is exhausted to the second exhauster 300, the inner pressures of the gas supply pipes 111a and 111b may decrease, and a flow rate controllability of each of the MFCs 115a and 115b may decrease. On the other hand, when the first switching valve 303a is provided downstream of the MFCs 115a and 115b, the fluctuation in the front stages of the MFCs 115a and 115b is suppressed in the gas supply pipes 111a and 111b. In such a case, even when supplying the gas is performed in the sequence shown in FIGS. 7 and 8, it is possible to suppress the fluctuation of the flow rate of the gas supplied to the chambers 100a and 100b. Thus, it is possible to suppress the deterioration of a process uniformity of the wafer 200. Further, by performing the first process gas supply step S203 after performing the first process gas exhaust step S401 with the configuration described above, it is possible to exhaust the gas without supplying the gas to the chambers 100a and 100b while a flow rate control of the gas in the MFCs 115a and 115b is fluctuating. When the source gas is supplied to the wafer 200 while the flow rate control of the gas in the MFCs 115a and 115b is fluctuating, the amount of the source gas supplied to the wafer 200 may be unclear, and the processing may not be performed as expected. However, with the configuration described above, it is possible to supply the source gas whose flow rate is determined by the MFCs 115a and 115b to the wafer 200, and it is also possible to improve the process uniformity of each of the wafers 200.

The above-described embodiments are described by way of an example in which the single wafer type substrate processing apparatus capable of processing the substrate one by one is used. However, the above-described technique is not limited thereto. For example, the above-described technique may also be applied to a batch type substrate processing apparatus in which a plurality of substrates are disposed in the process space in a vertical direction or a horizontal direction.

The above-described embodiments are described by way of an example in which the source gas and the reactive gas are alternately supplied to form the film. However, the above-described technique is not limited thereto. For example, the above-described technique may be applied to other methods as long as an amount of a gas phase reactive of the source gas and the reactive gas and the amount of by-products generated by the gas phase reactive are within an acceptable range. For example, the above-described technique may be applied even when the supply of the source gas and the supply of the reactive gas are at least partially overlapped.

The above-described embodiments are described by way of an example in which the process module includes a pair of chambers is used. However, the above-described technique is not limited thereto. For example, the above-described technique may also be applied to a process module including a set of three or more chambers.

The above-described embodiments are described by way of an example in which the single wafer type substrate processing apparatus capable of processing the substrate one by one is used. However, the above-described technique is not limited thereto. For example, the above-described technique may also be applied to a batch type substrate processing apparatus in which a plurality of substrates are disposed in the process chamber in a vertical direction or a horizontal direction.

The above-described embodiments are described by way of an example in which the film-forming process is performed. However, the above-described technique is not limited thereto. For example, the above-described technique may also be applied to other processes instead of the film-forming process. That is, the above-described technique may also be applied to a process such as a diffusion process, an oxidation process, a nitridation process, an oxynitridation process, a reduction process, an oxidation-reduction process, an etching process and a heating process. For example, the above-described technique may also be applied to a plasma oxidation process or a plasma nitridation process of a substrate or a film formed on the substrate using the reactive gas alone. The above-described technique may also be applied to a plasma annealing process using the reactive gas alone.

The above-described embodiments are described by way of an example in which the manufacturing process of the semiconductor device is performed. However, the above-described technique is not limited thereto. For example, the above-described technique may be applied to other manufacturing processes. For example, the above-described technique may be applied to a substrate processing such as a manufacturing process of a liquid crystal device, a manufacturing process of a solar cell, a manufacturing process of a light emitting device, a processing of a glass substrate, a processing of a ceramic substrate and a processing of a conductive substrate.

The above-described embodiments are described by way of an example in which the silicon oxide film (SiO film) is formed using the silicon-containing gas serving as the source gas and the oxygen-containing gas serving as the reactive gas. However, the above-described technique is not limited thereto. For example, the above-described technique may be applied to the formations of other films using different gases. For example, the above-described technique may also be applied to formations of an oxygen-containing film, a nitrogen-containing film, a carbon-containing film, a boron-containing film, a metal-containing film and combinations thereof. For example, the above-described technique may also be applied to formations of a silicon nitride (SiN) film, an aluminum oxide (AlO) film, a zirconium oxide (ZrO) film, a hafnium oxide (HfO) film, a hafnium aluminum oxide (HfAlO) film, a zirconium aluminum oxide (ZrAlO) film, a silicon carbide (SiC) film, a silicon carbonitride (SiCN) film, a silicon boronitride (SiBN) film, a titanium nitride (TiN) film, a titanium carbide (TiC) film and a titanium aluminum carbide (TiAlC) film. It is possible to obtain the same effects described above by appropriately changing supply positions of the source gas and the reactive gas and appropriately modifying the structures in the shower head 234 based on comparing the gas characteristics such as the adsorption, the desorption and the vapor pressure between the source gas and the reactive gas used in forming the above-described films;

As described above, according to some embodiments in the present disclosure, it is possible to exhaust the inner atmosphere of the gas supply pipe of the process vessel while preventing the exhaust gas from accumulating in the exhaust pipe of the process vessel in the substrate processing system including the plurality of the process vessels.

1. A substrate processing system comprising:
a plurality of process vessels capable of accommodating a substrate;
a source gas supply source;
a reactive gas supply source provided separately from the source gas supply source;
a gas supply pipe connected to each of the process vessels, wherein the gas supply pipe comprises:
a source gas supply pipe wherethrough a source gas supplied from the source gas supply source flows; and
a reactive gas supply pipe wherethrough a reactive gas supplied from the reactive gas supply source flows;
a first exhauster configured to exhaust inner atmospheres of the plurality of the process vessels;
a second exhauster provided separately from the first exhauster, configured to exhaust an inner atmosphere of the source gas supply pipe and connected to the source gas supply pipe through a first switching valve;
a third exhauster provided separately from the first exhauster and the second exhauster, configured to exhaust an inner atmosphere of the reactive gas supply pipe and connected to the reactive gas supply pipe; and
a controller capable of controlling the first switching valve, the first exhauster and the second exhauster to perform:
(a) processing the substrate by supplying the source gas through the source gas supply pipe to a process vessel among the plurality of the process vessels; and
(b) exhausting the source gas from the source gas supply pipe to the second exhauster while the source gas is not being supplied through the source gas supply pipe to the process vessel.

2. The substrate processing system of claim 1, wherein
the controller is capable of controlling the first switching valve such that the source gas is exhausted by the second exhauster in (b).

3. The substrate processing system of claim 2, further comprising
a detoxification apparatus provided downstream of the first exhauster, wherein the second exhauster is connected to the detoxification apparatus.

4. The substrate processing system of claim 2, further comprising
a tank provided downstream of the second exhauster and capable of storing a gas exhausted by the second exhauster.

5. (canceled)

6. The substrate processing system of claim 1,
wherein the third exhauster is connected to the reactive gas supply pipe through a second switching valve, and
the controller is capable of controlling the second switching valve such that the reactive gas is exhausted by the third exhauster.

7. The substrate processing system of claim 1 further comprising
a detoxification apparatus provided downstream of the first exhauster,
wherein the second exhauster is connected to the detoxification apparatus.

8. The substrate processing system of claim 1, further comprising
a tank provided downstream of the second exhauster and capable of storing a gas exhausted by the second exhauster.

9. (canceled)

10. The substrate processing system of claim 1, further comprising
a tank provided downstream of the second exhauster and capable of storing the source gas exhausted by the second exhauster without being supplied to the process vessel.

11. The substrate processing system of claim 10, further comprising:
a pressure meter capable of measuring an inner pressure of the tank; and
a display capable of displaying control contents of the controller,
wherein the controller is capable of notifying the display of the inner pressure of the tank after the inner pressure of the tank reaches a predetermined pressure value or more.

12. The substrate processing system of claim 10, wherein the controller is provided with a communication instrument capable of communicating with a host apparatus,
wherein the controller is capable of monitoring an inner pressure of the tank and controlling the communication instrument to notify the host apparatus of the inner pressure of the tank after the inner pressure of the tank reaches a predetermined pressure value or more.

13. The substrate processing system of claim 10, further comprising:
a pressure meter capable of measuring an inner pressure of the tank; and
a bypass line provided in parallel with the tank downstream of the second exhauster through a line switching valve in a manner that the bypass line passes through no tank,
wherein the controller is capable of controlling the line switching valve such that the gas exhausted by the second exhauster flows from the second exhauster to the bypass line after the inner pressure of the tank reaches a predetermined pressure value or more.

14. The substrate processing system of claim 10, wherein the tank is configured to be removable from an exhaust line provided with the second exhauster.

15. The substrate processing system of claim 10, further comprising
a temperature regulator capable of adjusting a temperature of the tank to a predetermined temperature.

16. The substrate processing system of claim 10, wherein the second exhauster comprises at least a gas exhaust pipe, an exhaust pump and a heater configured to adjust a temperature of the gas exhaust pipe to a predetermined temperature.

17. The substrate processing system of claim 16, wherein the gas exhaust pipe comprises a source gas exhaust pipe configured to exhaust the source gas, and
the controller is capable of controlling the heater so as to heat the gas exhaust pipe to a temperature that prevents the source gas from adhering to an inside of the gas exhaust pipe.

18. The substrate processing system of claim 1, further comprising:
a source gas exhaust pipe; and
a reactive gas exhaust pipe,
wherein
the source gas exhaust pipe is configured to exhaust the inner atmosphere of the source gas supply pipe,
the reactive gas exhaust pipe is configured to exhaust the inner atmosphere of the reactive gas supply pipe, and
the second exhauster communicates with either the source gas exhaust pipe or the reactive gas exhaust pipe through either the first switching valve or a second switching valve.

19. The substrate processing system of claim 1, wherein the second exhauster comprises at least a gas exhaust pipe, an exhaust pump and a heater configured to adjust a temperature of the gas exhaust pipe to a predetermined temperature.

20. The substrate processing system of claim 19, wherein the gas exhaust pipe comprises a source gas exhaust pipe configured to exhaust the source gas, and
the controller is capable of controlling the heater so as to heat the gas exhaust pipe to a temperature that prevents the source gas from adhering to an inside of the gas exhaust pipe.

21. The substrate processing system of claim 1, further comprising a bypass line provided downstream of the second exhauster so as to bypass a tank,
wherein the bypass line passes through no tank.

22. The substrate processing system of claim 10, further comprising
a detoxification apparatus provided downstream of the first exhauster,
wherein the second exhauster is connected to the detoxification apparatus.
